(19) United States
(12) Patent Application Publication
(10) Pub. No.: US 2025/0133656 A1
(43) Pub. Date: Apr. 24, 2025

(54) SEMICONDUCTOR PACKAGE

(71) Applicant: LG INNOTEK CO., LTD., Seoul (KR)

(72) Inventors: Sang Il KIM, Seoul (KR); Se Woong NA, Seoul (KR); Kee Han LEE, Seoul (KR)

(21) Appl. No.: 18/692,909

(22) PCT Filed: Sep. 16, 2022
(86) PCT No.: PCT/KR2022/013851

§ 371 Date: Mar. 18, 2024

(30) Foreign Application Priority Data
Sep. 16, 2021 (KR) 10-2021-0124359

(51) Int. Cl. H05K 1/11; H01L 21/48; H01L 23/00; H01L 23/31; H01L 23/538; H01L 25/065; H01L 25/18; H05K 1/18; H05K 3/28; H10B 80/00; H10D 80/30

(52) U.S. Cl. CPC H05K 1/113; H01L 23/3128; H05K 1/181; H05K 3/28; H01L 21/4857; H01L 21/486; H01L 23/5386; H01L 24/16; H01L 24/17; H01L 24/81; H01L 25/0655; H01L 25/18; H01L 2224/16227; H01L 2224/16237; H01L 2224/1703; H01L 2224/17055; H01L 2224/17106; H01L 2224/81203; H01L 2924/381; H01L 2924/3841; H05K 2201/09472; H05K 2203/1377; H10B 80/00; H10D 80/30

(57) ABSTRACT

A semiconductor package according to an embodiment includes an first insulating layer; a first pad disposed on the first insulating layer; and a first protective layer disposed on the first insulating layer and having a first through hole vertically overlapping the first pad, wherein an inner wall of the first through hole includes a contact surface in contact with a side surface of the first pad, and a non-contact surface located on the contact surface, and wherein a ratio of a thickness of the contact surface to a thickness of the first pad is 1:2 or more and less than 1:1.

### TECHNICAL FIELD

The embodiment relates to a circuit board and a semiconductor package including the same.

### BACKGROUND ART

Generally, a printed circuit board (PCB) is a laminated structure in which insulating layers and conductor layers are alternately laminated, and the conductor layers may be provided with a circuit pattern by patterning.

Such printed circuit board includes a solder resist SR that protects the circuit pattern formed on an outermost side of the laminate structure, prevents oxidation of the conductor layer, and serves as an insulator when electrically connected to a chip mounted on a printed circuit board or another board.

A typical solder resist includes an opening region (SRO: Solder Resist Opening) where connection means such as solder or bumps are combined to form an electrical connection path. The opening region of the solder resist is required as the I/O (Input/Output) performance improves as the high performance and density of printed circuit boards increase, thereby a small bump pitch of the opening region is required. At this time, the bump pitch of the opening region refers to a center distance between adjacent opening regions.

Meanwhile, the opening region SRO of the solder resist includes a Solder Mask Defined (SMD) type and a Non-Solder Mask Defined (NSMD) type.

The SMD type is characterized in that a width of the opening region SRO is smaller than a width of the pad exposed through the opening region SRO, and accordingly, in the SMD type, at least a portion of an upper surface of the pad is covered by the solder resist.

In addition, the NSMD type is characterized in that a width of the opening region SRO is larger than a width of the pad exposed through the opening region SRO, and accordingly, the solder resist in the NSMD type is spaced apart from the pad at a certain interval and has a structure in which both the upper and side surfaces of the pad are exposed.

However, in the case of the above SMD type, when testing the solder ball joint reliability of a bonding strength of the solder ball after a semiconductor package is connected to a main board, there is a problem in that the solder ball is separated from the pad exposed through the opening region SRO. Additionally, in the case of the NSMD type, there is a problem in that the pad on which the solder ball is disposed is separated from the circuit board. Accordingly, conventionally, an appropriate combination of SMD type and NSMD type is applied to one circuit board.

However, in the case of a circuit board including an opening region (SRO) of a conventional SMD type, a width of the opening region is smaller than a width of the pad, and accordingly, there is a problem in that a sufficient bonding area with the solder disposed on the pad is not secured.

In addition, in the case of a circuit board including an opening region (SRO) of a conventional SMD type, when performing a process of exposing the solder resist layer, there is a problem in that light is not sufficiently transmitted to a lower region of an exposure region of the solder resist layer, and accordingly, the lower region of the exposure region is not sufficiently cured. In addition, if a development process is performed in a state where the lower region of the exposure region is not sufficiently cured, there is a problem that undercut occurs in which the lower region of the exposure region is removed.

### DISCLOSURE

### Technical Problem

An embodiment provides a circuit board with a new structure and a semiconductor package including the same.

In addition, the embodiment provides a circuit board including a protective layer having a new type of opening region to solve the problems of an opening region (SRO) of SMD type and NSMD type, and a semiconductor package including the same.

In addition, the embodiment provides a circuit board and a semiconductor package including the same that can improve the flow of a connection part such as a solder ball disposed in an opening region of a protective layer.

In addition, the embodiment provides a circuit board and a semiconductor package including the same that can minimize a horizontal distance of a depression corresponding to an undercut in an opening of a protective layer while an entire region of an upper surface of a pad overlaps vertically with an opening of a protective layer.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package according to an embodiment comprises an first insulating layer; a first pad disposed on the first insulating layer; and a first protective layer disposed on the first insulating layer and having a first through hole vertically overlapping the first pad, wherein an inner wall of the first through hole includes a contact surface in contact with a side surface of the first pad, and a non-contact surface located on the contact surface, and wherein a ratio of a thickness of the contact surface to a thickness of the first pad is 1:2 or more and less than 1:1.

In addition, at least a portion of the non-contact surface overlaps the first pad in a horizontal direction.

In addition, the non-contact surface includes a first portion located on the contact surface, and a second portion located on the first portion, wherein the inner wall of the first through hole has a longest inner wall width along the horizontal direction, and wherein a width of the inner wall of the first portion gradually decreases toward the side surface of the first pad.

In addition, the first protective layer includes a region overlapping the first portion in a vertical direction and gradually decreasing in thickness toward the side surface of the first pad.

In addition, the first portion is inclined with respect to a lower surface of the first protective layer.

In addition, the first pad includes an overlapping portion overlapping the contact surface in a horizontal direction, and wherein a thickness of the overlapping portion satisfies a range of 50% to 98% of a thickness of the first pad.

In addition, a width of an inner wall of the first portion gradually increases as it approaches the second portion.

In addition, an internal angle between the first portion and the lower surface of the first protective layer satisfies the range of 10 degrees to 70 degrees.

In addition, a vertical length between the lower surface of the first protective layer and an uppermost end of the first portion satisfies the range of 70% to 130% of a vertical length between a lower surface and an upper surface of the first pad.

In addition, at least one of an upper and side surfaces of the first pad includes a curved surface.

In addition, an uppermost end of the first portion is located higher than the upper surface of the first pad.

In addition, an uppermost end of the first portion is located lower than the upper surface of the first pad.

In addition, at least one of the first portion and the second portion includes a curved surface having a curvature in the horizontal direction.

In addition, the second portion has a slope different from a slope of the first portion.

In addition, the slope of the second portion is closer to vertical than the slope of the first portion.

In addition, the width of the inner wall of the second portion does not change along the vertical direction.

In addition, the semiconductor further comprises a second pad on the first insulating layer and spaced apart from the first pad, the first protective layer includes a second through hole vertically overlapping the second pad, and wherein a vertical cross-sectional shape of the second through hole is different from that of the first through hole.

In addition, a width of the inner wall of the second through hole is smaller than the width of the second pad.

In addition, the second through hole includes a plurality of sub through holes overlapping one second pad in the vertical direction and spaced apart from each other in the horizontal direction.

In addition, the first through hole includes a depression provided between the first portion and the second portion and recessed toward an inside of the first protective layer away from the first pad.

In addition, the depression is located higher than the upper surface of the first pad.

In addition, the depression is located lower than the upper surface of the first pad.

### Advantageous Effects

An embodiment comprises a first protective layer disposed on the uppermost side of the circuit board. The first protective layer includes a first opening that vertically overlaps the first pad and has a greater width than the first pad. And, the first protective layer includes a first portion and a second portion disposed on the first portion. In addition, the first portion of the first protective layer includes a first-first portion in contact with a side surface of the first pad, and a first-second portion disposed on the first-first portion and spaced apart from a side of the first pad. Through this, the embodiment allows a portion of the side surface of the first pad to be covered through the first-first portion of the first protective layer.

Accordingly, the embodiment may allow a portion of the upper surface of the first insulating layer to not be exposed in the first region of the first protective layer where the first opening having a width greater than the width of the first pad is formed, and through this, the upper surface of the first insulating layer can be prevented from being damaged.

In addition, when forming the first opening in the first protective layer, the embodiment does not completely open the first protective layer, but allows only the region excluding the first-first portion to be partially opened. Accordingly, a process time can be dramatically reduced and the process yield can be improved accordingly.

Additionally, the embodiment may minimize a depth of the undercut, which increases in proportion to a depth of the first opening. That is, in the embodiment, a first opening is formed by partially developing only the region excluding a first-first portion, and accordingly, the depth of the undercut can be reduced, and further, the undercut that may be formed on a sidewall of the first protective layer having the first opening can be removed. In addition, the embodiment removes the undercut formed on the sidewall of the first protective layer or minimizes the depth of the undercut, and accordingly, a distance between the first pad and the trace adjacent to the first pad can be reduced. Through this, the embodiment can reduce the size of the circuit board or increase the circuit integration degree of the circuit board.

In addition, the embodiment may control a thickness of the first-first portion to reduce a height of a step between the first-first portion and the first pad, and accordingly, it is possible to solve the void problem that occurs when a connection part such as a solder ball is not completely filled within the first opening.

In addition, the second side wall of the first-second portion of the first protective layer has an inclination angle θ1 that is inclined toward the second portion as a distance from the first pad increases. Accordingly, the embodiment can improve the flowability of the connection part by using the inclination angle (θ1) in a process of applying the connection part within the first opening, and accordingly, the connection part can be stably applied on the first pad. Through this, the embodiment can improve adhesion between the first pad and the connection part, thereby improving electrical reliability and physical reliability.

### DESCRIPTION OF DRAWINGS

FIGS. 1 (a) and (b) are diagrams showing a circuit board according to a comparative example.

FIG. 2A is a cross-sectional view illustrating a semiconductor package according to a first embodiment.

FIG. 2B is a cross-sectional view illustrating a semiconductor package according to a second embodiment.

FIG. 2C is a cross-sectional view illustrating a semiconductor package according to a third embodiment.

FIG. 2D is a cross-sectional view illustrating a semiconductor package according to a fourth embodiment.

FIG. 2E is a cross-sectional view illustrating a semiconductor package according to a fifth embodiment.

FIG. 2F is a cross-sectional view illustrating a semiconductor package according to a sixth embodiment.

FIG. 2G is a cross-sectional view illustrating a semiconductor package according to a seventh embodiment.

FIG. 3A is a cross-sectional view of a circuit board according to an embodiment.

FIG. 3B is a top view of a first region of a circuit board of FIG. 3A.

FIG. 3C is a top view of a second region of a circuit board of FIG. 3A.

FIG. 4 is a diagram showing a first opening of a first protective layer according to a first embodiment.

FIG. 5 is a diagram showing a circuit board according to a second embodiment.

FIG. 6 is a diagram showing a circuit board according to a third embodiment.

FIG. 7 is a diagram showing a circuit board according to a fourth embodiment.

FIG. 8 is an optical microscope photo of an actual product corresponding to FIG. 7.

FIG. 9 is a diagram showing a package substrate according to an embodiment.

FIGS. 10A to 10I are diagrams showing the circuit board manufacturing method according to the first embodiment in orders of processes.

### MODES OF THE INVENTION

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, it will be understood that there are no intervening elements present.

As used herein, a singular expression includes a plural expression, unless the context clearly indicates otherwise.

It will be understood that the terms “comprise”, “include”, or “have” specify the presence of stated features, integers, steps, operations, elements, components and/or groups thereof disclosed in the present specification, but do not preclude the possibility of the presence or addition of one or more other features, integers, steps, operations, elements, components, and/or groups thereof.

Hereinafter, embodiments of the present invention will be described in detail with reference to the accompanying drawings.

### Comparison Example

Before describing the embodiment, a comparative example compared to the circuit board of the embodiment of the present application will be described.

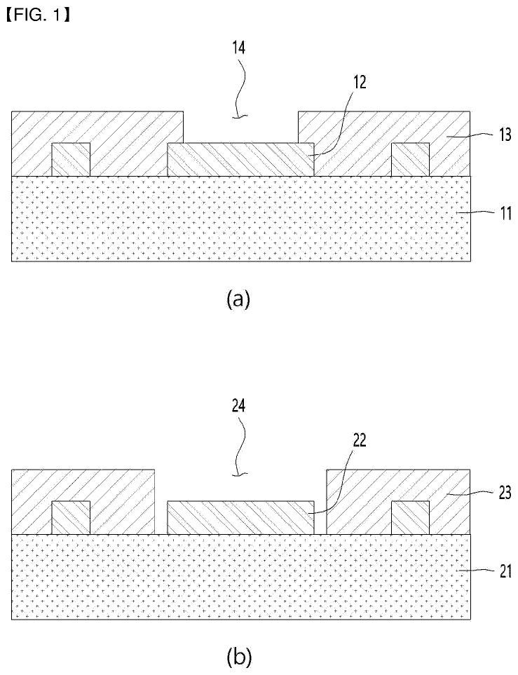

FIG. 1 is a diagram showing a circuit board according to a comparative example.

Referring to (a) of FIG. 1, the comparative example includes an insulating layer 11, a circuit pattern layer 12, and a protective layer 13.

At this time, the circuit pattern layer 12 includes a pad connected to a through electrode, on which a chip is mounted, or connected to a main board of an external substrate. Additionally, the circuit pattern layer 12 includes a trace, which is a signal line that extend long from a pad.

Additionally, a connection part (not shown) such as a solder ball for bonding to the main board or mounting a chip is disposed on the pad of the circuit pattern layer 12.

Accordingly, the protective layer 13 includes an opening 14 that vertically overlaps the pad.

The protective layer 13 is a solder resist disposed on an uppermost or lowermost side of the circuit board and protects the surface of the insulating layer 11.

At this time, as shown in (a) of FIG. 1, the opening 14 of the protective layer 13 in the first comparative example has a Solder Mask Defined type (SMD) type. For example, a width of the opening 14 of the protective layer 13 is smaller than a width of the circuit pattern layer 12. Accordingly, the pad includes an overlapping region that vertically overlaps the opening 14 and a non-overlapping region that does not vertically overlap the opening 14 and is covered with the protective layer 13.

At this time, in a case of the circuit board of the first comparative example including the opening 14 of the SMD type as described above, the opening 14 has a width smaller than that of the pad. Accordingly, when the connection part is disposed on the pad, the bonding area between the connection part and the pad becomes smaller than a total area of the pad. Accordingly, in the first comparative example, the bonding area between the pads of the connection part may not be secured, and accordingly, there is a problem in that the bonding force between the pad and the connection part is reduced. In addition, in the case of the above-mentioned problem, a reliability problem occurs in which the connection part is separated from the pad due to the stress that acts in various usage environments of the circuit board.

Referring to (b) of FIG. 1, the second comparative example includes an insulating layer 21, a circuit pattern layer 22, and a protective layer 23.

The protective layer 23 includes an opening 24 that vertically overlaps the pad of the circuit pattern layer 22.

At this time, as shown in (b) of FIG. 1, the opening 24 of the protective layer 23 in the second comparative example has a NSMD (Non Solder Mask Defined type) type. For example, a width of the opening 24 of the protective layer 23 is larger than the width of the circuit pattern layer 22. Accordingly, an entire region of the pad vertically overlaps the opening 24.

In the case of the NSMD type as described above, the opening 24 is formed to have a depth corresponding to an entire thickness of the protective layer 23 (thickness from an upper surface of the insulating layer to an upper surface of the protective layer).

However, in the exposure and curing process to form the opening 24 as described above, sufficient light is not supplied to a lower region of the protective layer 23 (a region adjacent to the upper surface of the insulating layer), and accordingly, there is a problem in that sufficient curing of the lower region is not achieved. Accordingly, the second comparative example has a problem in that undercut occurs in the lower region of the protective layer 23 due to insufficient hardening. At this time, a depth (e.g., horizontal distance) of the undercut increases in proportion to a thickness of the protective layer 23. In addition, in the second comparative example, there is a problem that a depth of the opening 24 increases as the opening 24 is formed with a depth corresponding to the entire thickness of the protective layer 23.

Additionally, in the second comparative example, the opening 24 is not completely filled with a connection part such as a solder ball, so an empty space such as a void exists.

Additionally, in the second comparative example, there is a surface step in the region where the connection part is placed corresponding to the thickness of the circuit pattern layer, and accordingly, there is a problem in which the connection part cannot be stably placed on the pad. For example, in the second comparative example, the connection part may be applied to a region that overlaps vertically with the exposed region rather than a region that overlaps vertically with the pad due to the surface step as described above, and this causes physical reliability and/or electrical reliability problems.

In addition, the performance of electrical/electronic products has recently been improved, and accordingly, technologies for attaching a larger number of packages to a limited-sized substrate are being researched. Accordingly, there is a demand for finer circuit patterns. However, in the case of a package substrate using the circuit board of the second comparative example, there is a limit to reducing the spacing between pads, traces, and between pads and traces constituting the circuit pattern layer due to the depth of the undercut described above. Additionally, recently, the number of functions processed in an application processor (AP) has increased, and it has become difficult to implement them in a single chip. However, when using the circuit board provided in the comparative example, it is difficult to mount two application processors (APs) performing different functions within a limited space.

The embodiment is intended to solve the problems of the comparative example, and provides a protective layer including a new type of opening to solve the problems of openings of the SMD type and NSMD type. Additionally, the embodiment makes it possible to improve the flowability of connection parts such as solder balls disposed within the opening region of the protective layer. In addition, the embodiment has a structure in which the entire upper surface of the pad vertically overlaps the opening of the protective layer, while minimizing the horizontal distance of the depression corresponding to the undercut in the opening of the protective layer.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one chip. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, a circuit board in one embodiment may be a first board described below.

In addition, a circuit board in another embodiment may be a second board described below.

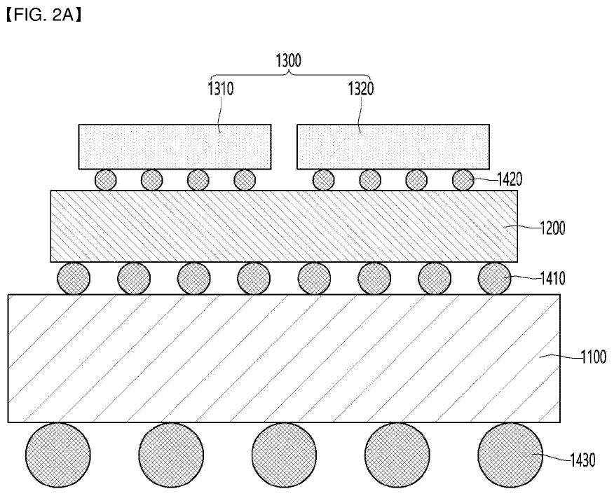

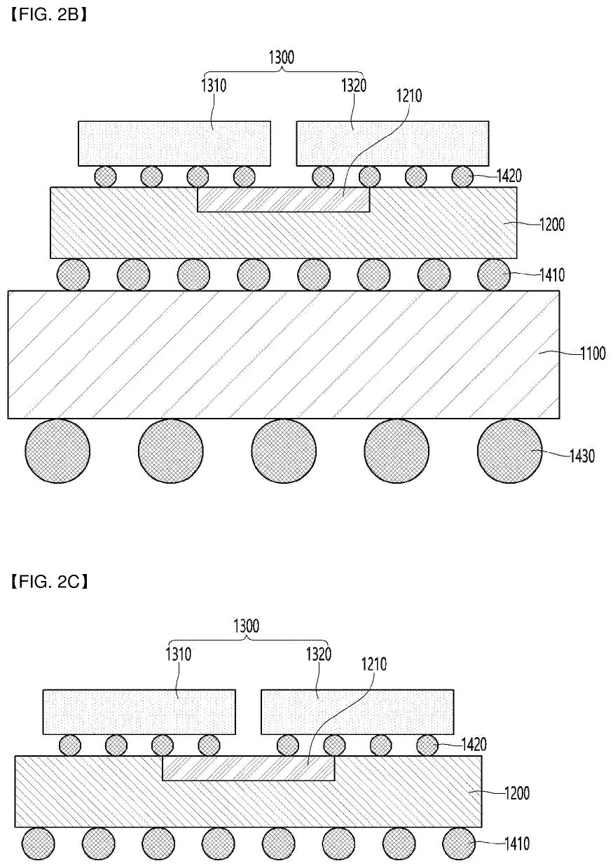

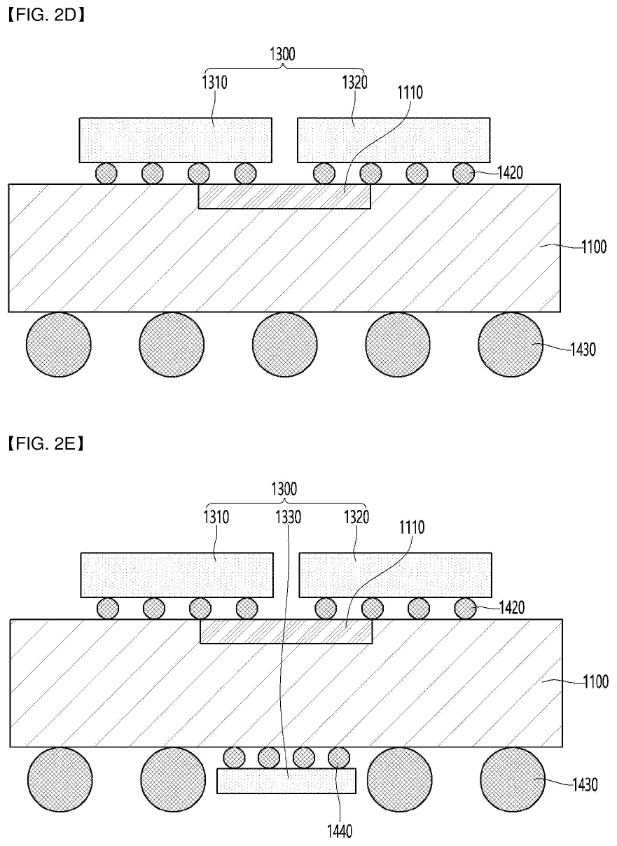

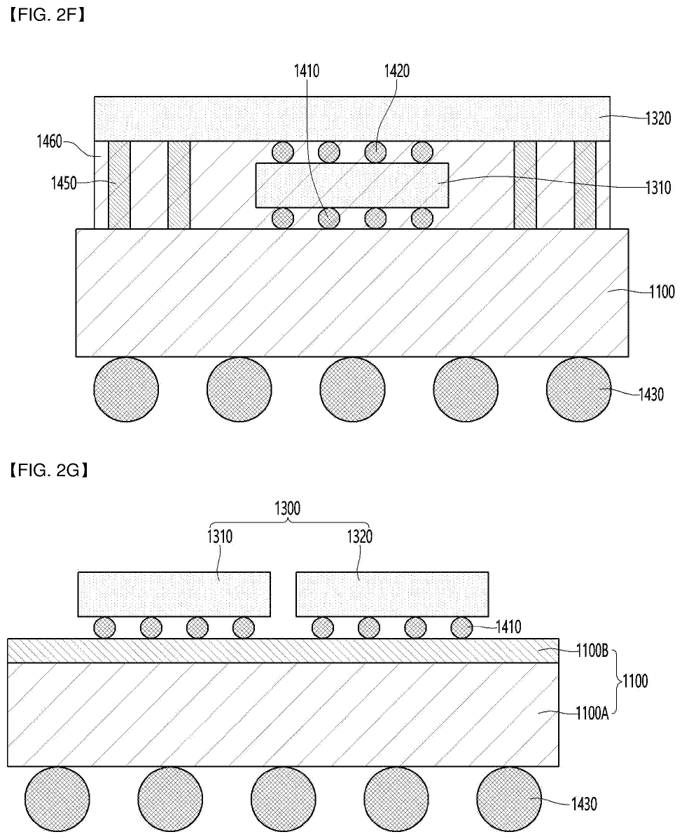

FIG. 2A is a cross-sectional view illustrating a semiconductor package according to a first embodiment, FIG. 2B is a cross-sectional view illustrating a semiconductor package according to a second embodiment, FIG. 2C is a cross-sectional view illustrating a semiconductor package according to a third embodiment, FIG. 2D is a cross-sectional view illustrating a semiconductor package according to a fourth embodiment, FIG. 2E is a cross-sectional view illustrating a semiconductor package according to a fifth embodiment, FIG. 2F is a cross-sectional view illustrating a semiconductor package according to a sixth embodiment, and FIG. 2G is a cross-sectional view illustrating a semiconductor package according to a seventh embodiment.

Referring to FIG. 2A, the semiconductor package according to the first embodiment may include a first circuit board 1100, a second circuit board 1200, and a semiconductor device 1300.

The first circuit board 1100 may mean a package substrate.

For example, the first circuit board 1100 may provide a space to which at least one external substrate is coupled. The external substrate may refer to a second circuit board 1200 coupled to the first circuit board 1100. Also, the external substrate may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 may include at least one insulating layer, an electrode part disposed on the at least one insulating layer, and a through electrode passing through the at least one insulating layer.

A second circuit board 1200 may be disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package substrate.

FIG. 2A illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one of the semiconductor device 1300 and the first circuit board 1100.

In one embodiment, the second circuit board 1200 may be an active interposer that functions as a semiconductor device. When the second circuit board 1200 functions as a semiconductor device, the semiconductor package of the embodiment may have a vertical stack structure on the first circuit board 1100 and function as a plurality of logic chips. Being able to have the functions of a logic chip may mean having the functions of an active device and a passive device. In the case of active devices, unlike passive devices, current and voltage characteristics may not be linear, and in the case of an active interposer, it can have the function of an active device. Additionally, the active interposer may function as a corresponding logic chip and perform a signal transmission function between the first circuit board 1100 and a second logic chip disposed on an upper portion of the active interposer.

According to another embodiment, the second circuit board 1200 may be a passive interposer. For example, the second circuit board 1200 may function as a signal relay between the semiconductor device 1300 and the first circuit board 1100, and may have passive device functions such as a resistor, capacitor, and inductor. For example, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

the semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment may include a connection part.

For example, the semiconductor package may include a first connection part 1410 disposed between the first circuit board 1100 and the second circuit board 1200. The first connection part 1410 may electrically connect the second circuit board 1200 to the first circuit board 1100 while coupling them.

For example, the semiconductor package may include the second connection part 1420 disposed between the second circuit board 1200 and the semiconductor device 1300. The second connection part 1420 may electrically connect the semiconductor device 1300 to the second circuit board 1200 while coupling them.

The semiconductor package may include a third connection part 1430 disposed on a lower surface of the first circuit board 1100. The third connection part 1430 may electrically connect the first circuit board 1100 to the main board while coupling them.

At this time, the first connection part 1410, the second connection part 1420, and the third connection part 1430 may electrically connect between the plurality of components by using at least one bonding method of wire bonding, solder bonding and metal-to-metal direct bonding. That is, since the first connection part 1410, the second connection part 1420, and the third connection part 1430 have a function of electrically connecting a plurality of components, when the metal-to-metal direct bonding is used, the connection part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. and to directly bond between the plurality of components. In addition, the metal-to-metal direct bonding method may refer to a bonding method by the second connection part 1420. In this case, the second connection part 1420 may mean a metal layer formed between a plurality of components by the recrystallization.

Specifically, the first connection part 1410, the second connection part 1420, and the third connection part 1430 may couple a plurality of components to each other by a thermal compression (TC) bonding method. The TC bonding may refer to a method of directly coupling a plurality of components by applying heat and pressure to the first connection part 1410, the second connection part 1420, and the third connection part 1430.

In this case, at least one of the first circuit board 1100 and the second circuit board 1200 may include a protrusion provided on the electrode where the first connection part 1410, the second connection part 1420, and the third connection part 1430 are disposed, and protruding in an outward direction away from the insulating layer of the corresponding circuit board. The protrusion may protrude outward from the first circuit board 1100 or the second circuit board 1200.

The protrusion may be referred to as a bump. The protrusion may also be referred to as a post. The protrusion may also be referred to as a pillar. Preferably, the protrusion may refer to an electrode on which a second connection part 1420 for coupling with the semiconductor device 1300 is disposed among the electrodes of the second circuit board 1200. That is, the pitch of the terminals of the semiconductor device 1300 is becoming finer, as a result, a short circuit may occur between the plurality of second connection parts 1420 respectively connected to the plurality of terminals of the semiconductor device 1300 by a conductive adhesive such as solder. Accordingly, the embodiment may perform thermal compression bonding to reduce the volume of the second connection part 1420. Accordingly, the embodiment may include a protrusion in the electrode of the second circuit board 1200 on which the second connection part 1420 is disposed in order to secure position accuracy and diffusion prevention power to prevent the intermetallic compound (IMC) formed between a conductive adhesive such as solder and a protrusion from diffusing to the interposer and/or the circuit board.

Meanwhile, referring to FIG. 2B, the semiconductor package of the second embodiment may differ from the semiconductor package of the first embodiment in that the connecting member 1210 is disposed on the second circuit board 1200. The connecting member 1210 may be referred to as a bridge substrate. For example, the connecting member 1210 may include a redistribution layer. The connecting member 1210 may function to electrically connect a plurality of semiconductor devices to each other horizontally. For example, an area that a semiconductor device should have, is generally too large, and for this reason, the connecting member 1210 may include a redistribution layer. The semiconductor package and the semiconductor device have significant differences in a width and a spacing of their circuit patterns, and for this reason, a buffering role of the circuit pattern for electrical connection is necessary. The buffering role may mean having an intermediate size between the width or spacing of the circuit pattern of the semiconductor package and the width or spacing of the circuit pattern of the semiconductor device, and the redistribution layer may include a function that acts as a buffer.

In an embodiment, the connecting member 1210 may be a silicon bridge. That is, the connecting member 1210 may include a silicon substrate and a redistribution layer disposed on the silicon substrate.

In another embodiment, the connecting member 1210 may be an organic bridge. For example, the connecting member 1210 may include an organic material. For example, the connecting member 1210 may include an organic substrate including an organic material instead of the silicon substrate.

The connecting member 1210 may be embedded in the second circuit board 1200, but is not limited thereto. For example, the connecting member 1210 may be disposed on the second circuit board 1200 to have a protruding structure.

Also, the second circuit board 1200 may include a cavity, and the connecting member 1210 may be disposed in the cavity of the second circuit board 1200.

The connecting member 1210 may horizontally connect a plurality of semiconductor devices disposed on the second circuit board 1200.

Referring to FIG. 2C, the semiconductor package according to the third embodiment may include a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a package substrate while performing an interposer function.

The first connection part 1410 disposed on the lower surface of the second circuit board 1200 may couple the second circuit board 1200 to the main board of the electronic device.

Referring to FIG. 2D, the semiconductor package according to the fourth embodiment may include a first circuit board 1100 and a semiconductor device 1300.

In this case, the semiconductor package of the fourth embodiment may have a structure in which the second circuit board 1200 is omitted compared to the semiconductor package of the second embodiment.

That is, the first circuit board 1100 of the fourth embodiment may function as a connection between the semiconductor device 1300 and the main board while functioning as a package substrate. To this end, the first circuit board 1100 may include a connecting member 1110 for connecting the plurality of semiconductor devices. The connecting member 1110 may be a silicon bridge or an organic material bridge connecting a plurality of semiconductor devices.

Referring to FIG. 2E, the semiconductor package of the fifth embodiment may further include a third semiconductor device 1330 compared to the semiconductor package of the fourth embodiment.

To this end, a fourth connection part 1440 may be disposed on the lower surface of the first circuit board 1100.

In addition, a third semiconductor device 1330 may be disposed on the fourth connection part 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 2C.

Referring to FIG. 2F, the semiconductor package according to the sixth embodiment may include a first circuit board 1100. A first semiconductor device 1310 may be disposed on the first circuit board 1100. To this end, a first connection part 1410 may be disposed between the first circuit board 1100 and the first semiconductor device 1310.

In addition, the first circuit board 1100 may include a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A second semiconductor device 1320 may be disposed on the conductive coupling portion 1450. In this case, the second semiconductor device 1320 may be connected to the first circuit board 1100 through the conductive coupling portion 1450. In addition, a second connection part 1420 may be disposed on the first semiconductor device 1310 and the second semiconductor device 1320.

Accordingly, the second semiconductor device 1320 may be electrically connected to the first semiconductor device 1310 through the second connection part 1420.

That is, the second semiconductor device 1320 may be connected to the first circuit board 1100 through the conductive coupling portion 1450, and may be also connected to the first semiconductor device 1310 through the second connection part 1420.

In this case, the second semiconductor device 1320 may receive a power signal and/or an electrical power through the conductive coupling portion 1450. Also, the second semiconductor device 1320 may transmit and receive a communication signal to and from the first semiconductor device 1310 through the second connection part 1420.

The semiconductor package according to the sixth embodiment provides a power signal and/or an electrical power to the second semiconductor device 1320 through the conductive coupling portion 1450, and it may be possible to provide sufficient power for driving the second semiconductor device 1320 or to smoothly control power supply operation.

Accordingly, the embodiment may improve the driving characteristics of the second semiconductor device 1320. That is, the embodiment may solve the problem of insufficient power provided to the second semiconductor device 1320. Furthermore, in the embodiment, at least one of the power signal, the electrical power and the communication signal of the second semiconductor device 1320 may be provided through different paths through the conductive coupling portion 1450 and the second connection part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of package substrates are stacked and may be disposed on the first substrate 1100. For example, the second semiconductor device 1320 may be a memory package including a memory chip. In addition, the memory package may be coupled on the conductive coupling portion 1450. In this case, the memory package may not be connected to the first semiconductor device 1310.

Meanwhile, the semiconductor package in the sixth embodiment may include a molding member 1460. The molding member 1460 may be disposed between the first circuit board 1100 and the second semiconductor device 1320. For example, the molding member 1460 may mold the first connection member 1410, the second connection member 1420, the first semiconductor device 1310, and the conductive coupling portion 1450.

Referring to FIG. 2G, the semiconductor package according to the seventh embodiment may include a first circuit board 1100, a first connection part 1410, a first connection part 1410, a semiconductor device 1300, and a third connection part 1430.

In this case, the semiconductor package of the seventh embodiment is different from the semiconductor package of the fourth embodiment in that the first circuit board 1100 includes a plurality of substrate layers while the connecting member 1110 is removed.

The first circuit board 1100 includes a plurality of substrate layers. For example, the first circuit board 1100 may include a first substrate layer 1100A corresponding to a package substrate and a second substrate layer 1100B corresponding to the connecting member.

In other words, the semiconductor package of the seventh embodiment may include a first substrate layer 1100A and a second substrate layer 1100B in which the first circuit board (package substrate, 1100) and the second circuit board (interposer, 1200) shown in FIG. 2A are integrally formed. The material of the insulating layer of the second substrate layer 1100B may be different from the material of the insulating layer of the first substrate layer 1100A. For example, the material of the insulating layer of the second substrate layer 1100B may include a photocurable material. For example, the second substrate layer 1100B may be a photo imageable dielectric (PID). In addition, since the second substrate layer 1100B includes a photocurable material, it is possible to miniaturize the electrode. Accordingly, in the seventh embodiment, the second substrate layer 1100B may be formed by sequentially stacking an insulating layer of a photo-curable material on the first substrate layer 1100A and forming a miniaturized electrode on the insulating layer of the photo-curable material. Through this, the second circuit board 1100B may be a redistribution layer including a miniaturized electrode and include a function to horizontally connect a plurality of semiconductor devices 1310 and 1320.

### —Circuit Board—

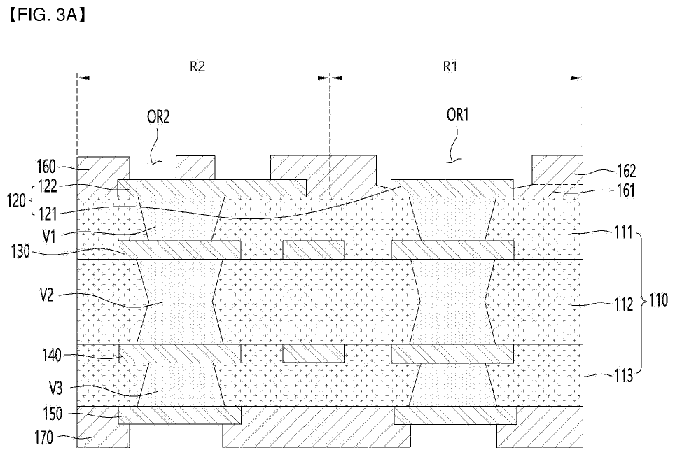

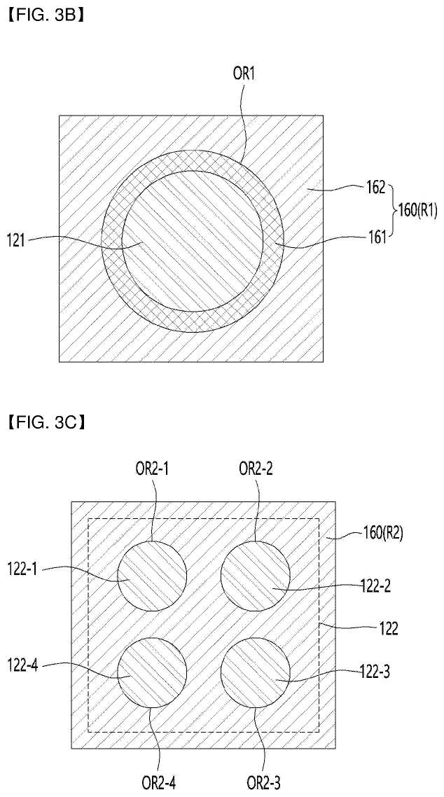

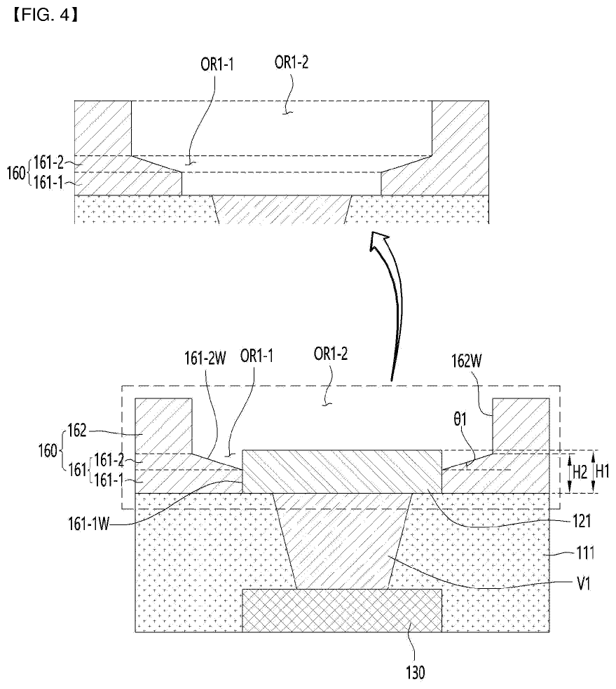

FIG. 3A is a cross-sectional view of a circuit board according to an embodiment, FIG. 3B is a top view of a first region of a circuit board of FIG. 3A, and FIG. 3C is a top view of a second region of a circuit board of FIG. 3A.

Before describing the circuit board of the embodiment, a circuit board described below may refer to any one circuit board among a plurality of circuit boards included in a previous semiconductor package.

For example, the circuit board described below may refer to any one of the first circuit board 1100, the second circuit board 1200, and the connection member (or bridge board, 1110, 1210) shown in any one of FIGS. 2A to 2G.

Hereinafter, the circuit board according to the first embodiment will be described in detail with reference to FIGS. 3A, 3B and 3C.

Referring to FIGS. 3A, 3B, and 3C, the circuit board includes an insulating layer 110, a circuit pattern layer, a through electrode, and a protective layer.

The insulating layer 110 may have a multiple layer structure. For example, an insulating layer 110 may include a first insulating layer 111, a second insulating layer 112, and a third insulating layer 113. At this time, the circuit board is shown in the drawing as having a three-layer structure based on the number of insulating layers, but it is not limited thereto. For example, the circuit board may have a structure (including single-layer structure) of two or less layers based on the number of insulating layers, or, alternatively, may have a structure of four or more layers based on the number of insulating layers.

For example, the first insulating layer 111 may be a first outermost insulating layer disposed at an first outermost side in a multi-layer structure. For example, the first insulating layer 111 may be an insulating layer disposed at an uppermost side of the circuit board. The second insulating layer 112 may be an inner insulating layer disposed at an inside of a multi-layered circuit board. The third insulating layer 113 may be a second outermost insulating layer disposed at the second outermost side in a multi-layer structure. For example, the third insulating layer 113 may be an insulating layer disposed at a lowermost side of the circuit board. In addition, the inner insulating layer is shown as consisting of one layer, if the circuit board has a layer structure of four or more layers, the inner insulating layer may have a layer structure of two or more layers.

The insulating layer 110 is a board equipped with an electric circuit whose wiring can be changed, and may include a print, a wiring board, and an insulating board made of an insulating material capable of forming circuit patterns on the surface.

For example, at least one of the insulating layer 110 may be rigid or flexible. For example, at least one of the insulating layer 110 may include glass or plastic. Specifically, the insulating layer 110 may include a chemically tempered/semi-tempered glass, such as soda lime glass, aluminosilicate glass, etc., a tempered or flexible plastic such as polyimide (PI), polyethylene terephthalate (PET), propylene glycol (PPG), polycarbonate (PC), etc., or sapphire.

In addition, at least one of the insulating layer 110 may include an optically isotropic film. For example, at least one of the insulating layer 110 may include cyclic olefin copolymer (COC), cyclic olefin polymer (COP), optically isotropic PC, optically isotropic polymethylmethacrylate (PMMA), or the like.

In addition, at least one of the insulating layer 110 may be formed of a material including an inorganic filler and an insulating resin. For example, at least one of the insulating layer 330 may be formed of a resin containing reinforcing materials such as inorganic fillers such as silica and alumina together with a thermosetting resin such as an epoxy resin or a thermoplastic resin such as polyimide, specifically Ajinomoto Build-up Film (ABF), FR-4, Bismaleimide Triazine (BT), Photo Imageable Dielectric resin (PID), BT, or the like.

In addition, at least one of the insulating layers 110 may have a partially curved surface and be curved. That is, at least one of the insulating layers 110 is partially flat, and at least one of the insulating layers 110 may have a partially curved surface and be bent. In detail, at least one end of the insulating layer 110 may have a curved surface and be bent, or at least one end of the insulating layer 110 has a surface with random curvature and may be curved or bent.

A circuit pattern layer may be disposed on a surface of the insulating layer 110.

For example, a first circuit pattern layer 120 may be disposed on a first or upper surface of the first insulating layer 111. For example, a second circuit pattern layer 130 may be disposed between a second surface or lower surface of the first insulating layer 111 and a first surface or upper surface of the second insulating layer 112. For example, a third circuit pattern layer 140 may be disposed between a second surface or lower surface of the second insulating layer 112 and a first surface or upper surface of the third insulating layer 113. For example, a fourth circuit pattern layer 150 may be disposed on a second or lower surface of the third insulating layer 113. A first circuit pattern layer 120 may be a circuit pattern layer disposed at a first outermost side or uppermost side of the circuit board. Additionally, the second circuit pattern layer 130 and the third circuit pattern layer 140 may be inner circuit pattern layers disposed inside the circuit board. Additionally, the fourth circuit pattern layer 150 may be a circuit pattern layer disposed at a second outermost side or lowermost side of the circuit board.

The first circuit pattern layer 120, the second circuit pattern layer 130, the third circuit pattern layer 140, and the fourth circuit pattern layer 150 is a wire that transmits electrical signals and may be formed of a metal material with high electrical conductivity. The first circuit pattern layer 120, the second circuit pattern layer 130, the third circuit pattern layer 140, and the fourth circuit pattern layer 150 may be formed of at least one metal material selected from among gold (Au), silver (Ag), platinum (Pt), titanium (Ti), tin (Sn), copper (Cu), and zinc (Zn). In addition, the first circuit pattern layer 120, the second circuit pattern layer 130, the third circuit pattern layer 140, and the fourth circuit pattern layer 150 may be formed of paste or solder paste including at least one metal material selected from among gold (Au), silver (Ag), platinum (Pt), titanium (Ti), tin (Sn), copper (Cu), and zinc (Zn), which are excellent in bonding force. Preferably, the first circuit pattern layer 120, the second circuit pattern layer 130, the third circuit pattern layer 140, and the fourth circuit pattern layer 150 may be formed of copper (Cu) having high electrical or thermal conductivity and a relatively low cost.

The first circuit pattern layer 120, the second circuit pattern layer 130, the third circuit pattern layer 140, and the fourth circuit pattern layer 150 can be formed using an additive process, a subtractive process, a modified semi additive process (MSAP) and a semi additive process (SAP), which is a typical circuit board manufacturing process, and a detailed description will be omitted here.

Meanwhile, each of the first to fourth circuit pattern layers 120, 130, 140, and 150 includes traces and pads.

The trace refers to a long line-shaped wiring that transmits electrical signals. Additionally, the pad may refer to a mounting pad on which components such as chips are mounted, a core pad or BGA pad for connection to an external board, or a pad connected to a through electrode.

A through electrode may be formed in the insulating layer 110. The through electrode is formed to pass through the insulating layer 110, and thus can electrically connect circuit pattern layers arranged in different layers.

For example, a first through electrode V1 may be formed in the first insulating layer 111. The first through electrode V1 passes through the first insulating layer 111, and thus can electrically connect the first circuit pattern layer 120 and the second circuit pattern layer 130.

For example, a second through electrode V2 may be formed in the second insulating layer 112. The second through electrode V2 passes through the second insulating layer 112, and thus can electrically connect the second circuit pattern layer 130 and the third circuit pattern layer 140. At this time, the second insulating layer 112 may be a core layer. And, when the second insulating layer 112 is a core layer, the second through electrode V2 may have an hourglass shape. However, the embodiment is not limited thereto. For example, when the circuit board of the embodiment is a coreless board, the second through electrode V2 may have a same shape as the first through electrode V1 or the third through electrode V3.

For example, a third through electrode V3 may be formed in the third insulating layer 113. The third through electrode V3 passes through the third insulating layer 113, and thus can electrically connect the third circuit pattern layer 140 and the fourth circuit pattern layer 150.

The through electrodes V1, V2 and V3 as described above may be formed by filling the inside of a through hole formed in each insulating layer with a metal material. The through hole may be formed by any one of mechanical, laser, and chemical processing. When the via hole is formed by mechanical processing, a method such as milling, drilling and routing may be used, when the via hole is formed by laser processing, a method of UV or CO2 laser may be used, when the via hole is formed by chemical processing, a chemical including amino silane, ketones, or the like may be used. Accordingly, at least one insulating layer among the plurality of insulating layers may be opened.

When the through hole is formed, the through electrodes V1, V2, and V3 may be formed by filling the inside of the through hole with a conductive material. The metal material forming the through electrodes V1, V2, and V3 may be any one selected from among copper (Cu), silver (Ag), tin (Sn), gold (Au), nickel (Ni), and palladium (Pd). In addition, the conductive material may be filled by any one of electroless plating, electroplating, screen printing, sputtering, evaporation, ink jetting, and dispensing, or a combination thereof.

Meanwhile, a first protective layer 160 may be disposed on the first or upper surface of the first insulating layer 111. The first protective layer 160 may include a solder resist. The first protective layer 160 may include openings OR1 and OR2 exposing a surface of the first circuit pattern layer 120. For example, the first protective layer 160 may include openings OR1 and OR2 exposing the pads 121 and 122 of the first circuit pattern layer 120. Meanwhile, the openings OR1 and OR2 may also be expressed as through holes passing through the first protective layer 160.

Correspondingly, a second protective layer 170 may be disposed on the second surface of the third insulating layer 113. The second protective layer 170 may include a solder resist. The second protective layer 170 may include an opening (not shown) exposing a surface of the pad (not shown) of the fourth circuit pattern layer 150.

Hereinafter, a structure of the opening of the first protective layer 160 of the embodiment will be described in detail.

The first protective layer 160 of the embodiment may include a first region R1 and a second region R2. The first region R1 and the second region R2 may be distinguished by a difference in a shape of an opening formed in the first protective layer 160.

For example, the first protective layer 160 may be divided into a first region R1 including a first opening OR1 and a second region R2 including a second opening OR2.

For example, the first protective layer 160 may include a first opening OR1 of a first type and a second opening OR2 of a second type. Also, the first opening OR1 of the first type and the second opening OR2 of the second type may have different shapes or structures. However, the embodiment is not limited thereto, and the first protective layer 160 may include only the first opening OR1 of the first type.

For example, the first protective layer 160 is divided into the first region R1 and the second region R2 according to the vertically overlapping pads of the first circuit pattern layer 120, and the first region R1 and the second region R2 may include first openings OR1 and second openings OR2 of different types, respectively.

Specifically, the first circuit pattern layer 120 includes a first pad 121 and a second pad 122. The first pad 121 and the second pad 122 may have different widths.

For example, the first pad 121 may have a first width. Additionally, the second pad 122 may have a second width that is larger than the first width of the first pad 121.

The first pad 121 and the second pad 122 may be pads that perform different functions. For example, the first pad 121 and the second pad 122 may be pads connected to a chip. Additionally, the first pad 121 may be a pad connected 1:1 to one terminal of the chip. Alternatively, the second pad 122 may be a pad connected 1:N to N terminals of the chip (N is 2 or more). For example, the second pad 122 may be a ground pad commonly connected to N terminals of the chip. For example, the second pad 122 may be a heat dissipation pad commonly connected to N terminals of the chip. However, the embodiment is not limited thereto, and the second pad 122 may be a pad that is commonly connected to the N terminals of the chip and performs a different function.

In addition, although it has been described that the second pad 122 is commonly connected to N terminals of the chip, the present invention is not limited thereto. For example, the second pad 122 may be connected 1:1 to one terminal of the chip. However, the second pad 122 may have a second width that is relatively larger than the first width of the first pad 121.

The first protective layer 160 may include a first opening OR1 that vertically overlaps the first pad 121. Additionally, the first protective layer 160 may include a second opening OR2 that vertically overlaps the second pad 122. At this time, the first opening OR1 and the second opening OR2 may be of different types. Here, the type can be distinguished based on the width of the pad that vertically overlaps the opening, compared to the width of the opening.

For example, the first opening OR1 may vertically overlap the first pad 121 and have a third width that is larger than the first width of the first pad 121.

Alternatively, the second opening OR2 may vertically overlap the second pad 122 and have a fourth width that is smaller than the second width of the second pad 122.

Accordingly, the first protective layer 160 does not vertically overlap the first pad 121, but partially overlaps the second pad 122 vertically and can be disposed on the first insulating layer 111.

At this time, in the embodiment, the first region R1 of the first protective layer 160 may contact at least a portion of a side surface of the first pad 121 while including a first opening OR1 having a width greater than the width of the first pad 121. For example, in a region where a protective layer of NSMD type is formed having an opening with a width larger than the width of the pad of the second comparative example, a side surface of the pad is not in contact with the protective layer. Unlike this, the first region R1 of the first protective layer 160 in the embodiment has a structure that contacts at least a portion of a side surface of the first pad 121, while including a first opening OR1 having a width greater than the first pad 121. Accordingly, an entire region of the upper surface of the first insulating layer 111 in the first region R1 of the first protective layer 160 may be covered with the first protective layer 160.

That is, in the second comparative example, at least a portion of the upper surface of the insulating layer in the region where the protective layer of NSMD type is formed is not covered by the protective layer. In addition, the upper surface not covered by the protective layer has a structure that is exposed to an outside during the manufacturing process of the circuit board, and as a result, there is a problem that damage occurs due to various factors.

In contrast, in the embodiment, in the first region R1 of the first protective layer 160, an entire region of the upper surface of the first insulating layer 111 is covered with the first protective layer 160. Accordingly, it can be protected from damage caused by various factors such as the above. In addition, the embodiment allows the first region R1 of the first protective layer 160 to have a structure that surrounds at least a portion of the side surface of the first pad 121 as described above, so that physical reliability problems such as collapse of the first pad 121 or film separation from the first insulating layer 111 can be solved.

Specifically, referring to FIG. 3B, the first region R1 of the first protective layer 160 may be divided into a plurality of parts in a thickness direction of the circuit board.

For example, the first region R1 of the first protective layer 160 may include a first portion 161 disposed on the first insulating layer 111 and a second portion 162 disposed on the first portion 161.

The first portion 161 of the first protective layer 160 may be disposed on the first insulating layer 111 and may contact at least a portion of the side surface of the first pad 121. For example, the side surface of the first pad 121 may include a contact region that directly contacts the first portion 161 of the first protective layer 160. Additionally, the side surface of the first pad 121 may include a non-contact region that does not contact the first portion 161 of the first protective layer 160. For example, the first portion 161 of the first protective layer 160 may overlap the first pad 121 horizontally.

The first portion 161 of the first protective layer 160 is disposed on the first insulating layer 111, surrounding at least a portion of the side surface of the first pad 121. Accordingly, the first portion 161 of the first protective layer 160 may function to support the first pad 121. Additionally, the first portion 161 of the first protective layer 160 can improve the flowability of connection parts such as solder balls disposed in the first opening OR1 of the first protective layer 160. For example, a sidewall (described later) of the first portion 161 of the first protective layer 160 may have a certain slope with respect to the upper surface of the first insulating layer 111, and accordingly, the connection part can be guided to be stably placed on the first pad 121.

The second portion 162 of the first protective layer 160 is disposed on the first portion 161. The second portion 162 of the first protective layer 160 may not be in contact with the first pad 121. For example, the second portion 162 of the first protective layer 160 may be spaced apart from the first pad 121. For example, the second portion 162 of the first protective layer 160 may include a first opening OR1 having a width greater than the width of the first pad 121. Through this, the upper surface of the first pad 121 may not vertically overlap the first protective layer 160. For example, an entire upper surface region of the first pad 121 may vertically overlap the first opening OR1 of the first protective layer 160.

Meanwhile, referring to FIG. 3C, the second region R2 of the first protective layer 160 may include a second opening OR2 that vertically overlaps the second pad 122. At this time, the second opening OR2 has a width smaller than the width of the second pad 122. For example, the second opening OR2 may partially overlap the second pad 122 in a vertical direction. For example, the upper surface of the second pad 122 may include a first overlapping region that vertically overlaps the second opening OR2 and a first non-overlapping region that does not vertically overlap the second opening OR2. For example, the upper surface of the second pad 122 may include a first overlapping region vertically overlapping the second opening OR2, and a first non-overlapping region that does not vertically overlap the second opening OR2. For example, the upper surface of the second pad 122 may include a second overlapping region corresponding to the first non-overlapping region that vertically overlaps the second region R2 of the first protective layer 160. For example, the upper surface of the second pad 122 may include a second non-overlapping region that does not vertically overlap the second region R2 of the first protective layer 160 and corresponding to the first overlapping region. Through this, the upper surface of the second pad 122 may be partially covered with the first protective layer 160. Through this, the upper surface of the second pad 122 may be partially exposed through the second opening OR2 of the first protective layer 160.

At this time, the second pad 122 in one embodiment is commonly connected to a plurality of terminals of the chip, as described above. Accordingly, the second region R2 of the first protective layer 160 may include a plurality of second openings. For example, a plurality of second openings in a form of dots may be formed in the second region of the first protective layer 160.

For example, the upper surface of the second pad 122 may include a portion covered by the second region R2 of the first protective layer 160, and an exposed portion that vertically overlaps the second opening OR2 of the first protective layer 160. And, the exposed portion of the second pad 122 may include a first exposed portion 122-1, a second exposed portion 122-2, a third exposed portion 122-3, and a fourth exposed portion 122-4 that are spaced apart from each other.

In addition, the second region R2 of the first protective layer 160 may include second-first to second-fourth openings that vertically overlap the first to fourth exposed portions of the second pad 122, respectively.

For example, the second opening OR2 of the first protective layer 160 may include a second-first opening OR2-1 that vertically overlaps the first exposed portion 122-1. For example, the second opening OR2 may include a second-second opening OR2-2 that vertically overlaps the second exposed portion 122-2. For example, the second opening OR2 may include a second-third opening OR2-3 that vertically overlaps the third exposed portion 122-3. For example, the second opening OR2 may include a second-fourth opening OR2-4 that vertically overlaps the fourth exposed portion 122-4.

That is, as described above, the second opening OR2 of the second type may have a width smaller than the width of the second pad 122. In addition, the second opening OR2 of the second type may include openings second-first to second-fourth that are spaced apart from each other and overlap the upper surface of the second pad 122, respectively. However, the embodiment is not limited thereto, and the second region R2 of the first protective layer 160 may include only one of the second-first to second-fourth openings that vertically overlap the upper surface of the second pad 122.

Hereinafter, the first opening OR1 formed in the first region R1 of the first protective layer 160 according to an embodiment will be described in detail.

FIG. 4 is a diagram showing a first opening of the first protective layer according to the first embodiment.

Referring to FIG. 4, the first protective layer 160 is disposed on the first insulating layer 111. At this time, the first protective layer 160 in the first region R1 does not vertically overlap the first pad 121.

The first protective layer 160 may be divided into a plurality of portions in the thickness direction of the circuit board.

For example, the first protective layer 160 may include a first portion 161 disposed on the first insulating layer 111 and a second portion 162 disposed on the first portion 161.

Also, a width of the first portion 161 and a width of the second portion 162 may be different from each other. For example, the width of the first portion 161 may be larger than the width of the second portion 162.

Through this, the first portion 161 of the first protective layer 160 may contact the side surface of the first pad 121. For example, at least a portion of the side surface of the first pad 121 may be in direct contact with the first portion 161 of the first protective layer 160. For example, at least a portion of the side surface of the first pad 121 may be covered with the first portion 161 of the first protective layer 160. Through this, at least a portion of the side surface of the first pad 121 can be supported by the first portion 161 of the first protective layer 160, and accordingly, the physical reliability of the first pad 121 can be improved. Additionally, the embodiment allows the first portion 161 of the first protective layer 160 to contact the side of the first pad 121, so that the upper surface of the first insulating layer 111 in the first region R1 may be covered by the first portion 161 of the first protective layer 160. Through this, the embodiment can stably protect the upper surface of the first insulating layer 111 while exposing the entire upper surface of the first pad 121. Through this, the embodiment can prevent the upper surface of the first insulating layer 111 from being damaged from various factors during the circuit board manufacturing process and thus improve product reliability.

The upper surface 161-2W of the first portion 161 may be inclined with respect to the upper surface of the first insulating layer 111, the lower surface of the first pad 121, or the lower surface of the first protective layer 160. For example, the upper surface 161-2W of the first portion 161 may be an inclined surface having a certain inclination angle.

Additionally, the upper surface 161-2W of the first portion 161 of the first protective layer 160 may horizontally overlap a portion of the side surface of the first pad 121.

Specifically, a portion of the side surface of the first pad 121 may be covered with the first portion 161, while overlapping vertically with the side of the first portion 161. In addition, the remaining portion of the side surface of the first pad 121 horizontally overlaps the upper surface 161-2W of the first portion 161, and can be spaced apart from the first portion 161 of the first protective layer 160.

The upper surface 161-2W of the first portion 161 of the first protective layer 160 may also be referred to as a side wall forming a part of the first opening OR1.

For example, the first portion 161 of the first protective layer 160 may be divided into a plurality of sub-portions in the thickness direction.

For example, the first portion 161 of the first protective layer 160 includes a first-first portion 161-1 disposed on the upper surface of the first insulating layer 111, and the first-second portion 162 disposed on the first-second portion 161-1.

The first-first portion 161-1 of the first protective layer 160 may have an opening that vertically overlaps the first pad 121. In this case, the opening of the first-first portion 161-1 does not mean an opening artificially formed through exposure and development processes like other openings in the embodiment. That is, the opening of the first-first portion 161-1 may mean a portion in the region where the first pad 121 is disposed where the first protective layer 160 is not formed.

For example, the first protective layer 160 is disposed on the first insulating layer 111 and the first pad 121 when the first pad 121 is formed, and accordingly, exposure and development processes to form the first opening OR1 are performed. At this time, the opening of the first-first portion 161-1 of the first protective layer 160 may mean a portion where the first protective layer 160 is not applied, by applying the first protective layer 160 with the first pad 121 disposed. For example, the opening of the first-first portion 161-1 of the first protective layer 160 may be a through portion or a through hole through which the first pad 121 passes.

A first side wall 161-1W of the first-first portion 161-1 may directly contact a portion of the side surface of the first pad 121. For example, the first side wall 161-1W of the first-first portion 161-1 may be formed to cover a portion of the side surface of the first pad 121. The first side wall 161-1W of the first-first portion 161-1 may be said to be a contact surface that contacts the side surface of the first pad 121.

A ratio of a thickness of the contact surface (for example, a thickness of the first-first portion 161-1) and the thickness H1 of the first pad 121 may be 1:2 or more and less than 1:1. For example, the thickness of the contact surface (e.g., the thickness of the first-first portion 161-1) may be 50% or more to less than 100% of the thickness H1 of the first pad 121.

Preferably, a height of the first side wall 161-1W of the first-first portion 161-1 of the first protective layer 160 may be lower than the height of the first pad 121. For example, the thickness of the first-first portion 161-1 may be smaller than the thickness H1 of the first pad 121. The thickness of the first-first portion 161-1 of the first protective layer 160 may range from 50% to 98% of the thickness H1 of the first pad 121. The thickness of the first-first portion 161-1 of the first protective layer 160 may range from 52% to 95% of the thickness H1 of the first-first portion 161-1 of the first protective layer 160. The thickness of the first-first portion 161-1 of the first protective layer 160 may range from 55% to 90% of the thickness H1 of the first pad 121. At this time, the thickness H1 of the first pad 121 may refer to a thickness of the first pad 121 after an etching process, which will be described below. However, the embodiment is not limited thereto. The thickness can also be expressed as a vertical length. For example, the thickness H1 of the first pad 121 may mean a vertical distance from an uppermost surface to a lowermost surface of the first pad 121.

Additionally, if the range is expressed differently, the side surface of the first pad 121 may include a contact portion that does not contact the first protective layer 160. For example, the side surface of the first pad 121 may include an overlapping portion that overlaps the contact surface in the horizontal direction. Additionally, the vertical length or thickness of the overlapping portion may range from 50% to 98%, or 52% to 95%, or 55% to 90% of the vertical length or thickness of the first pad 121.

If the thickness of the first-first portion 161-1 of the first protective layer 160 is less than 50% of the thickness H1 of the first pad 121, a depression may be formed between the sidewall of the first portion 161 and the second portion 162 of the first protective layer 160, and a horizontal distance of the depression formed may increase. If the thickness of the first-first portion 161-1 of the first protective layer 160 is less than 50% of the thickness H1 of the first pad 121, a step height may increase due to a difference between the thickness of the first-first portion 161-1 of the first protective layer 160 and the thickness H1 of the first pad 121. And, when the step height increases, problems may occur in the reliability of connection parts such as solder balls disposed in the first opening OR1 of the first protective layer 160. For example, when the step height increases, a problem may occur in which the connection part is not stably placed on the first pad 121. For example, the first opening OR1 includes an overlapping region that vertically overlaps the first pad 121, and a non-overlapping region that does not vertically overlap the first pad 121. Additionally, the connection part must be disposed in an overlapping region that overlaps the first pad 121 within the first opening OR1. However, when the step height increases, a problem may occur in which the connection part is placed biased toward a non-overlapping region rather than the overlapping region, and this may cause reliability problems. Additionally, when the step height increases, the first opening OR1 may not be completely filled with connection parts such as solder balls, and as a result, a void problem such as an empty space may occur.

Additionally, if the thickness of the first-first portion 161-1 of the first protective layer 160 is greater than 98% of the thickness H1 of the first pad 121, a problem may occur in which at least a portion of the first-first portion 161-1 is disposed on the upper surface of the first pad 121. For example, if the thickness of the first-first portion 161-1 of the first protective layer 160 is greater than 98% of the thickness H1 of the first pad 121, process errors occur in the exposure and development process of the first protective layer 160, and as a result, there is a problem in which the first opening OR1 is not formed in some of the regions vertically overlapping with the first pad 121. Through this, a problem may occur in which a portion of the upper surface of the first pad 121 is covered with the first protective layer 160. And, when a portion of the upper surface of the first pad 121 is covered with the first protective layer 160, problems may occur in electrical connectivity between the first pad 121 and the connection part, and electrical reliability problems such as circuit disconnection may occur accordingly.

Meanwhile, the thickness of the first-first portion 161-1 of the first protective layer 160 may be uniform in a width direction or a length direction, but is not limited thereto. This will be explained below.

Additionally, the first portion 161 of the first protective layer 160 may include a first-second portion 161-2 disposed on the first-first portion 161-1.

At this time, as in the above description, the second side wall 161-2W of the first-second portion 161-2 of the first protective layer 160 may also be expressed as an upper surface 161-2W of the first portion 161 of the first protective layer 160.

At least a portion of the second side wall 161-2W of the first-second portion 161-2 of the first protective layer 160 may not be in contact with the side surface of the first pad 121.

For example, the second side wall 161-2W of the first-second portion 161-2 of the first protective layer 160 may be inclined in a direction away from the first pad 121. The second side wall 161-2W of the first-second portion 161-2 of the first protective layer 160 may be a part of the first opening OR1. For example, the first opening OR1 may include a first-first opening OR1-1 formed in the first-second portion 161-2. Also, the second side wall 161-2W of the first-second portion 161-2 may mean an inner wall of the first-second opening OR1-1. At this time, at least a portion of the second side wall 161-2W may overlap the first pad 121 horizontally. That is, the first-first opening OR1-1 in the embodiment may overlap the first pad 121 vertically and horizontally with the first pad 121.

The second side wall 161-2W of the first-second portion 161-2 may be inclined with respect to an upper surface of the first insulating layer 111 or a lower surface of the first protective layer 160, or a lower surface of the first pad 121.

For example, an inclination angle θ1 of the second side wall 161-2W of the first-second portion 161-2 with respect to the upper surface of the first insulating layer 111 or the lower surface of the first protective layer 160 or the lower surface of the first pad 121 can satisfy a range between 10 degrees and 70 degrees. For example, the inclination angle θ1 of the second side wall 161-2W may satisfy a range between 15 degrees and 65 degrees. For example, the inclination angle θ1 of the second side wall 161-2W may satisfy a range between 20 degrees and 60 degrees.

At this time, the inclination angle θ1 may mean an internal angle between the second side wall 161-2W and the upper surface of the first insulating layer 111 vertically overlapping the second side wall 161-2W. For example, the inclination angle θ1 may mean an internal angle between the lower surface of the first protective layer 160 vertically overlapping the second side wall 161-2W and the second side wall 161-2W. For example, the inclination angle θ1 may mean an internal angle between the upper surface of the first-first portion 161-1 and the second side wall 161-2W.

Meanwhile, in the drawing, the second side wall 161-2W of the first-second portion 161-2 is shown as having a straight line corresponding to the inclination angle θ1, but the present invention is not limited thereto. For example, the second side wall 161-2W of the first-second portion 161-2 may be curved, and for example, at least a portion the second side wall 161-2W may be rounded. Accordingly, the inclination angle θ1 may mean an average inclination angle of the first-second portion 161-2 of the second side wall 161-2W. Differently, the inclination angle θ1 may mean an inclination angle of a straight line connecting one end of the second side wall 161-2W connected to the first side wall 161-1W of the first-first portion 161-1 and the other end of the second side wall 161-2W connected to the third side wall 162W of the second portion 162.

Meanwhile, if the inclination angle θ1 of the second side wall 161-2W of the first-second portion 161-2 is lower than 10 degrees or greater than 70 degrees, a problem may occur in which the thickness of the first-first portion 161-1 does not satisfy a range of 50% to 98% of the thickness H1 of the first pad 121. For example, the fact that the inclination angle θ1 of the second sidewall 161-2W of the first-second portion 161-2 may be lower than 10 degrees or greater than 70 degrees may mean that a depth of the first opening OR1 is less than or greater than a target depth. Accordingly, if the inclination angle θ1 of the second side wall 161-2W of the first-second portion 161-2 is lower than 10 degrees or greater than 70 degrees, a problem occurs in which the upper surface of the first pad 121 is covered by the first protective layer 160, a problem in which the height of the step increases, or a problem in which the horizontal distance of the depression increases, and this may result in electrical reliability problems and physical reliability problems.

Accordingly, the embodiment allows the inclination angle θ1 of the second side wall 161-2W of the first-second portion 161-2 to range between 10 degrees and 70 degrees. Accordingly, the embodiment can lower a height of the step between an upper surface of the first pad 121 and the second side wall 161-2W, and prevent depression from being included in the second side wall 161-2W.

Furthermore, the embodiment allows the inclination angle θ1 of the second side wall 161-2W of the first-second portion 161-2 to range between 10 degrees and 70 degrees, so that the flowability of connection parts such as solder balls disposed in the first opening OR1 of the first protective layer 160 can be improved. For example, the second side wall 161-2W of the first-second portion 161-2 may have an inclination angle θ1 that inclines toward the second portion 162 of the first protective layer 160 as the distance from the first pad 121 increases. In addition, the second side wall 161-2W may have the same inclination angle θ1 as above, so that the connection part can be induced to flow to a position corresponding to the first pad 121, thereby improving electrical and physical reliability between the connection part and the first pad 121. For example, when applying a connection part within the first opening OR1, the connection part may move onto the first pad 121 as it flows along the second side wall 161-2W. Accordingly, the embodiment can improve the flowability of the connection part and the adhesion between the connection part and the first pad 121.

The second side wall 161-2W of the first-second portion 161-2 has an inclination angle θ1 corresponding to the range described above, so that the thickness of the first-second portion 161-2 may change in the longitudinal or width direction. For example, the first-second portion 161-2 may include a region whose thickness gradually increases corresponding to the inclination angle θ1 in a longitudinal or width direction. For example, the first-second portion 161-2 may include a region whose thickness gradually increases as it moves away from the first pad 121.

In addition, the second side wall 161-2W of the first-second portion 161-2 has an inclination angle θ1 corresponding to the range described above, so that a first-first opening OR1-1 constituting the second side wall 161-2W corresponding to the inclination angle θ1 may be formed in the first-second portion 161-2. Also, the width of the first-first opening OR1-1 may change in the thickness direction. For example, the width of the first-first opening OR1-1 of the first-second portion 161-2 may change in response to the inclination angle θ1 as it goes toward the thickness direction. For example, the first-first opening OR1-1 of the first-second portion 161-2 may increase in width as it moves away from the first-first portion 161-1 or as it approaches the second portion 162. Also, the degree of increase in the width of the first-first opening OR1-1 may correspond to the inclination angle θ1 of the second side wall 161-2W. Here, the change in width may mean that the width gradually changes (e.g., gradually increases or gradually decreases).

At this time, the width of the opening may mean the width of the inner wall of the opening. At this time, a cross-sectional shape of the opening may have various shapes. For example, the cross-sectional shape may be circular. For example, the cross-sectional shape may be oval. For example, the cross-sectional shape may be any one of a triangular shape, a square shape, and a polygonal shape. At this time, the inner wall width may mean a width at a longest distance along the horizontal direction from the opening. For example, when a planar shape of the opening is square, the width of the inner wall may mean a width of an inner wall in a diagonal direction connecting two opposing vertices of a square-shaped opening.

At this time, a position of an uppermost end of the first-second portion 161-2 corresponds to a target depth of the first opening set in a development process for forming the first opening. That is, the embodiment allows the opening to have a depth corresponding to the height of the uppermost end of the first-second portion 161-2 or the height of the uppermost end of the second side wall 161-2W. At this time, the embodiment allows additional development to be performed in the portion adjacent to the first pad during the development process, and accordingly, the second side wall 161-2W can have the inclination angle θ1 as described above.

And, in one embodiment, the uppermost end of the first-second portion 161-2 may be located lower than the upper surface of the first pad 121. However, the uppermost end of the first-second portion 161-2 may be located at a height similar to the upper surface of the first pad 121. For example, in another embodiment, the uppermost end of the first-second portion 161-2 (e.g., uppermost end of the second side wall) may be located higher than the upper surface of the first pad 121.

Meanwhile, the first pad 121 is etched according to the removal of debris after the first opening OR1 is formed in the first protective layer 160. At this time, the uppermost end of the first-second portion 161-2 is located lower than the upper surface of the first pad 121 before the etching. However, the uppermost end of the first-second portion 161-2 after etching of the first pad 121 may be located lower than the upper surface of the first pad 121, or alternatively, it may be located higher than the upper surface of the first pad 121.

For example, the height H2 of the uppermost end of the first-second portion 161-2 or the uppermost end of the second side wall 161-2W may satisfy a range of 70% to 130% of the height H1 of the upper surface of the first pad 121. For example, the height H2 of the uppermost end of the first-second portion 161-2 or the uppermost end of the second side wall 161-2W may satisfy a range of 75% to 125% of the height H1 of the upper surface of the first pad 121. For example, the height H2 of the uppermost end of the first-second portion 161-2 or the uppermost end of the second side wall 161-2W may satisfy a range of 80% to 120% of the height H1 of the upper surface of the first pad 121.

If the height H2 of the uppermost end of the first-second portion 161-2 or the uppermost end of the second side wall 161-2W is lower than 70% of the height H1 of the upper surface of the first pad 121, the height of the first-first portion 161-1 of the first protective layer 160 may be correspondingly reduced, and as a result, a step height as described above may increase, or a depression may be formed in the second side wall 161-2W.

In addition, the fact that the height H2 of the uppermost end of the first-second portion 161-2 or the uppermost end of the second side wall 161-2W is greater than 130% of the height H1 of the first pad 121 means that the first pad 121 has been over-etched in a state where the first opening OR1 is formed in the first protective layer 160 with a normal depth. Accordingly, the resistance of the first pad 121 increases, thereby reducing signal transmission loss. In addition, the fact that the height H2 of the uppermost end of the first-second portion 161-2 or the uppermost end of the second side wall 161-2W is greater than 130% of the height H1 of the first pad 121 means that the first opening OR1 is not formed with a target depth in a state in which the first pad 121 is normally etched. In addition, if the first opening OR1 does not have the target depth, a problem may occur in which at least a portion of the upper surface of the first pad 121 is covered with the first protective layer 160, which may result in an electrical reliability problem.

Accordingly, the embodiment allows the height H2 of the uppermost end of the first-second portion 161-2 or the uppermost end of the second side wall 161-2W to satisfy the range of 70% to 130% of the height H1 of the first pad 121, and accordingly, the reliability of the first pad 121 and the reliability of the first opening OR1 of the first protective layer 160 can be improved.

Meanwhile, the first protective layer 160 includes a second portion 162 disposed on the first-second portion 161-2.

The second portion 162 of the first protective layer 160 may include a first-second opening OR1-2 that is a part of the first opening OR1 that vertically overlaps the first pad 121 of the first protective layer 160, while being connected to the first-first opening OR1-1.

The first-second opening OR1-2 of the second portion 162 of the first protective layer 160 has a width greater than that of the first pad 121. Accordingly, at least a portion of the second side wall 161-2W of the first-second portion 161-2 may vertically overlap the first-second opening OR1-2. For example, the first-second opening OR1-2 of the second portion 162 of the first protective layer 160 may include a first overlapping region vertically overlapping the first pad 121 and a second overlapping region vertically overlapping the second sidewall 161-2W of the first-second portion 161-2 without vertically overlapping the first pad 121.

The first-second opening OR1-2 of the second portion 162 may include a region having a width greater than the width of one region of the first-first opening OR1-1. Additionally, the first-second opening OR1-2 of the second portion 162 may include a region whose width is smaller than the width of another region of the first-first opening OR1-1. Additionally, the first-second opening OR1-2 of the second portion 162 may include a region having a width equal to the width of another region of the first-first opening OR1-1.

Meanwhile, in the drawing, the first-second opening OR1-2 of the second portion 161 is shown to have a uniform width in the thickness direction (i.e., has the same width throughout the entire region), but the embodiment is not limited thereto. For example, the first-second opening OR1-2 of the second portion 162 may include a region whose width varies. For example, the second portion 162 includes a third side wall 162W corresponding to the first-second opening OR1-2. Also, the third side wall 162W of the second portion 162 may have a certain inclination with respect to the upper surface of the first insulating layer 111. For example, the third side wall 162W of the second portion 162 may be curved rather than flat. For example, the third side wall 162W of the second portion 162 may include a rounded portion.

As described above, the first region R1 of the first protective layer 160 in the first embodiment includes a first opening OR1 having a width greater than that of the first pad 121 while vertically overlapping the first pad 121.

And, the first protective layer 160 includes a first portion 161 disposed on the upper surface of the first insulating layer 111 and a second portion 162 disposed on the first portion 161.

In addition, the first portion 161 of the first protective layer 160 includes a first-first portion 161-1 in contact with the side surface of the first pad 121 and a first-second portion 161-2 disposed on the first-first portion 161-1 and spaced apart from the side of the first pad 121. And, in the embodiment, a portion of the side surface of the first pad 121 is covered through the first-first portion 161-1. Through this, the embodiment allows the first opening OR1 in the first region R1 to have a width greater than the width of the first pad 121. Accordingly, a problem of a portion of the upper surface of the first insulating layer being exposed can be solved, and thus damage to the upper surface of the first insulating layer can be prevented. Additionally, when forming the first opening OR1 in the first protective layer 160, a process time can be dramatically reduced by partially opening only the region excluding the first-first portion 161-1, rather than opening the first protective layer 160 as a whole, as a result, process yield can be improved. Additionally, the embodiment can solve the problem that the undercut depth increases in proportion to the depth of the first opening OR1. For example, in the embodiment, the first opening OR1 is formed by partially developing only the region excluding the first-first portion 161-1, and accordingly, the depth of the undercut can be reduced, and further, the undercut can be prevented from being formed on the sidewall of the first protective layer 160 having the first opening OR1. In addition, the embodiment can control the thickness of the first-first portion 161-1 and reduce the height of the step between the first-first portion 161-1 and the first pad. Accordingly, it is possible to solve the void problem that occurs when a connection part such as a solder ball is not completely filled within the first opening. Additionally, the second side wall 161-2W of the first-second portion 161-2 has an inclination angle θ1 that inclines toward the second portion 162 as the distance from the first pad 121 increases. Accordingly, the flowability of the connection part can be improved by using the inclination angle θ1 in the process of applying the connection part within the first opening OR1, and accordingly, the connection part can be placed on the first pad 121 vertically overlapping the first opening OR1. Through this, the embodiment can improve adhesion between the first pad and the connection part, thereby improving electrical reliability and physical reliability.

Meanwhile, if the structure of the circuit board of the embodiment is expressed differently, the circuit board comprises an first insulating layer; a first pad disposed on the first insulating layer; and a first protective layer disposed on the first insulating layer and having a first through hole vertically overlapping the first pad, wherein an inner wall of the first through hole includes a contact surface in contact with a side surface of the first pad, and a non-contact surface located on the contact surface, and wherein a ratio of a thickness of the contact surface to a thickness of the first pad is 1:2 or more and less than 1:1. In addition, at least a portion of the non-contact surface overlaps the first pad in a horizontal direction. In addition, the non-contact surface includes a first portion located on the contact surface, and a second portion located on the first portion, the inner wall of the first through hole has a longest inner wall width along the horizontal direction, and a width of the inner wall of the first portion gradually decreases toward the side surface of the first pad. In addition, the first protective layer includes a region overlapping the first portion in a vertical direction and gradually decreasing in thickness toward the side surface of the first pad. In addition, the first portion is inclined with respect to a lower surface of the first protective layer. In addition, the first pad includes an overlapping portion overlapping the contact surface in a horizontal direction, and wherein a thickness of the overlapping portion satisfies a range of 50% to 98% of a thickness of the first pad. In addition, a width of an inner wall of the first portion gradually increases as it approaches the second portion. In addition, an internal angle between the first portion and the lower surface of the first protective layer satisfies the range of 10 degrees to 70 degrees. In addition, a vertical length between the lower surface of the first protective layer and an uppermost end of the first portion satisfies the range of 70% to 130% of a vertical length between a lower surface and an upper surface of the first pad.

In addition, at least one of an upper and side surfaces of the first pad includes a curved surface. In addition, an uppermost end of the first portion is located higher than the upper surface of the first pad. In addition, an uppermost end of the first portion is located lower than the upper surface of the first pad. In addition, at least one of the first portion and the second portion includes a curved surface having a curvature in the horizontal direction. In addition, the second portion has a slope different from a slope of the first portion. In addition, the slope of the second portion is closer to vertical than the slope of the first portion. In addition, the width of the inner wall of the second portion does not change along the vertical direction. In addition, the semiconductor further comprises a second pad on the first insulating layer and spaced apart from the first pad, the first protective layer includes a second through hole vertically overlapping the second pad, and wherein a vertical cross-sectional shape of the second through hole is different from that of the first through hole. In addition, a width of the inner wall of the second through hole is smaller than the width of the second pad. In addition, the second through hole includes a plurality of sub through holes overlapping one second pad in the vertical direction and spaced apart from each other in the horizontal direction. In addition, the first through hole includes a depression provided between the first portion and the second portion and recessed toward an inside of the first protective layer away from the first pad. In addition, the depression is located higher than the upper surface of the first pad. In addition, the depression is located lower than the upper surface of the first pad.

Hereinafter, a modified example of the shape of the first opening of the first protective layer will be described, using the circuit board of the first embodiment shown in FIGS. 3A to 3C as the basic structure. However, hereinafter, descriptions that are substantially the same or overlapping with those of FIGS. 3A to 3C will be omitted for convenience.

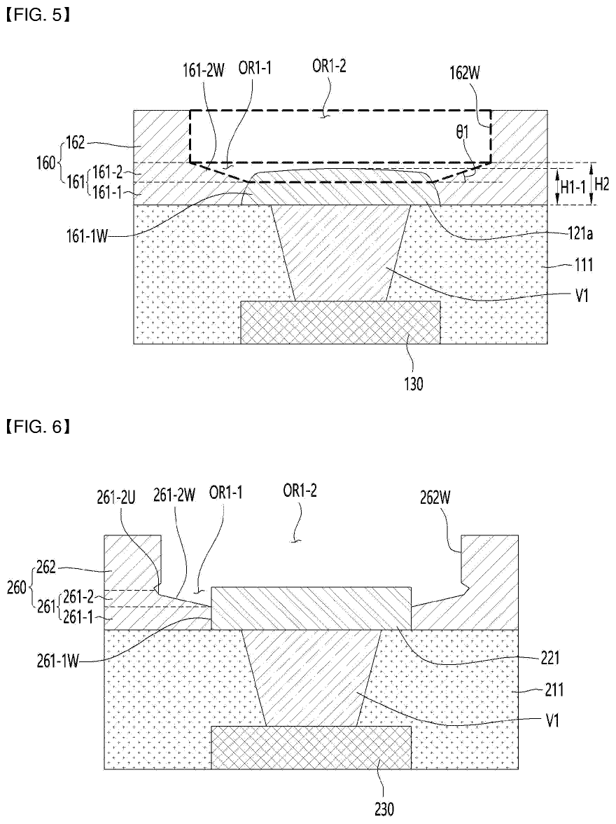

FIG. 5 is a diagram showing a circuit board according to a second embodiment.

Referring to FIG. 5, the circuit board according to the second embodiment is substantially the same as the circuit board of FIG. 4, but differs in the shape of the first pad.

For example, the first pad 121 in the circuit board of FIG. 4 has a rectangular vertical cross-sectional shape. For example, the first pad 121 in the circuit board of FIG. 4 has a pillar shape with the upper and lower widths being the same.

Alternatively, upper and lower widths of the first pad 121a in the circuit board according to the second embodiment of FIG. 5 may be different from each other. For example, the width of the upper surface of the first pad 121a may be smaller than the width of the lower surface. For example, the first pad 121a may include a region whose width decreases as it moves away from the upper surface of the first insulating layer 111.

Additionally, at least a portion of the first pad 121a may include a curved surface. For example, at least a portion of the first pad 121a may include a rounded portion. For example, the upper surface of the first pad 121a may include a curved surface that is convex in an upward direction. For example, a boundary surface between the upper surface and a side surface of the first pad 121a may include a curved surface.

The first pad 121a as described above may be formed through an etching process for removing debris.

For example, in the embodiment, when the first pad 121a is formed, a first protective layer 160 is formed to cover the first pad 121a, and accordingly, the first opening OR1 is formed through a process of opening a region of the first protective layer 160 that vertically overlaps the first pad 121a. At this time, even if the upper surface of the first pad 121a is entirely exposed through the first opening OR1, the first protective layer 160 may remain on a portion of the upper or side surface of the first pad 121a.

Accordingly, in a process of manufacturing the circuit board, a process of removing the debris by etching the surface of the first pad 121a that is not covered with the first protective layer 160 is process is performed after forming the first opening OR1 in the first protective layer 160.

Through this, the first pad 121a may have a convex curved upper surface through the etching process, the boundary surface between the upper surface and the side surface may include a curved surface, and the width of the upper surface and the lower width may vary.

Additionally, a height of the first pad 121a before the etching process is different from a height of the first pad 121a after the etching process. Specifically, the height of the first pad 121a after the etching process is smaller than the height of the first pad 121a before the etching process.

Accordingly, a height H2 of the uppermost end of the first-second portion 161-2 of the first protective layer 160 or the uppermost end of the second side wall 161-2W before the etching the first pad 121a is smaller than the height of the first pad 121a before the etching.

At this time, after the first pad 121a is etched, the height of the first pad 121a decreases, and accordingly, the height H2 of the uppermost end of the first-second portion 161-2 of the first protective layer 160 or the uppermost end of the second side wall 161-2W may be greater than the height H1-1 of the first pad 121a after the etching. However, the embodiment is not limited thereto, and the height H2 of the uppermost end of the first-second portion 161-2 of the first protective layer 160 or the uppermost end of the second side wall 161-2W may be smaller than the height H1-1 of the second pad 121a after the etching.

Specifically, as described above, the height H2 of the uppermost end of the first-second portion 161-2 of the first protective layer 160 or the uppermost end of the second side wall 161-2W may satisfy a range of 70% to 130% of the height H1-1 of the first pad 121a after the etching. For example, the height H2 of the uppermost end of the first-second portion 161-2 or the uppermost end of the second side wall 161-2W may satisfy a range of 75% to 125% of the height H1-1 of the top surface of the first pad 121a after the etching. For example, the height H2 of the uppermost end of the first-second portion 161-2 or the uppermost end of the second side wall 161-2W may satisfy a range of 80% to 120% of the height H1-1 of the upper surface of the first pad 121a after the etching.

FIG. 6 is a diagram showing a circuit board according to a third embodiment.

Referring to FIG. 6, the circuit board according to the third embodiment includes a first insulating layer 211. Additionally, the first pad 221 of the first circuit pattern layer is disposed on the first insulating layer 211. Additionally, a first protective layer 260 including a first opening vertically overlapping the first pad 221 is disposed on the first insulating layer 211.

At this time, the first protective layer 260 includes a first portion 261 and a second portion 262 disposed on the first portion 261.

The first portion 261 of the first protective layer 260 includes a first-first portion 261-1 disposed on the upper surface of the first insulating layer 211 and including a first side wall 261-1W in direct contact with at least a portion of the side surface of the first pad 221.

Additionally, the first-second portion 261-2 includes a first-first opening OR1-1 including a second side wall 261-2W having a certain inclination angle with respect to the upper surface of the first insulating layer 211.

Additionally, the second portion 262 of the first protective layer a first-second opening OR1-2 disposed on the first-second portion 261-2 and connected to the first-first opening OR1-1. Additionally, the second portion 262 of the first protective layer may include a third side wall 262W corresponding to the first-second opening OR1-2.

At this time, the above structure is substantially the same as the circuit board of the first embodiment described with reference to FIG. 4, and therefore detailed description thereof will be omitted.

Meanwhile, the first protective layer 260 in the embodiment may include a depression 261-2U. The depression 261-2U may refer to an undercut portion of the side wall of the first protective layer 260 that is depressed in an inner direction (or a direction away from the first pad) of the first protective layer 260.

At this time, the embodiment allows the second side wall 261-2W of the first-second portion 261-2 to have a certain inclination angle. Accordingly, the depth of the first opening OR1 that opens the first protective layer 260 can be reduced, and the depth (e.g., horizontal distance) of the depression 261-2U can be reduced.

For example, the first-second portion 261-2 and the second portion 262 of the first protective layer 260 in the embodiment can be distinguished by a position of the depression 261-2U. For example, the boundary for distinguishing between the first-second portion 261-2 and the second portion 262 of the first protective layer 260 can be determined based on the position where the depression 261-2U was formed. For example, at least a portion of the depression 261-2U may be formed on the second side wall 261-2W of the first-second portion 261-2. Additionally, at least a remaining portion of the depression 261-2U may be formed on the third side wall 262W of the second portion 262.

Meanwhile, in the embodiment, the width of the first opening OR1 may have a maximum width in the region where the depression 261-2U is formed.

The depression 261-2U may have a certain angle. At this time, the angle of the depression 261-2U may mean the inclination angle of the side wall of the depression 261-2U. For example, the depression 261-2U may include a first depression side wall connected to the second side wall 261-2W of the first-second portion 261-2 and a second depression side wall connected to the third side wall 262W of the second portion 262. And, the angle of the depression 261-2U may mean an internal angle between the first depression sidewall and the second depression sidewall. At this time, the angle of the depression 261-2U may be greater than the inclination angle θ1 of the side wall of the first-first opening OR1-1.

At this time, as described above, the embodiment may allow adjusting the height of the uppermost end of the first-second portion 261-2 and thereby adjusting the position where the depression 261-2U is formed. Through this, the embodiment can allow the depression 261-2U to be located at a height substantially similar to the upper surface of the first pad 221. At this time, in the comparative example, the depression was formed at a height substantially corresponding to the lower surface of the pad. In contrast, the embodiment allows the position of the depression 261-2U to be formed at a height corresponding to the upper surface of the first pad 221. Through this, the embodiment can move the position of the depression 261-2U upward by a height corresponding to the thickness of the first pad 221, and increase the angle of the depression 261-2U in proportion to the distance the depression 261-2U has moved. Through this, the depth (or horizontal distance) of the depression 261-2U can be reduced compared to the comparative example.

Accordingly, the embodiment can further improve product satisfaction by reducing the depth of the depression 261-2U. The depression 261-2U will be described in more detail below.

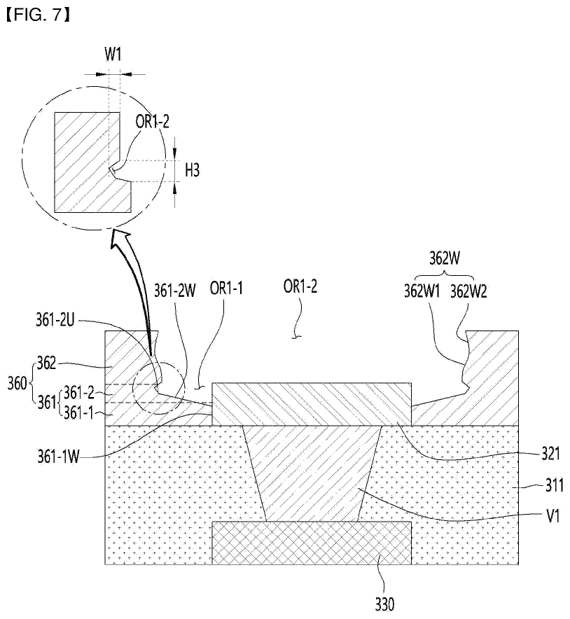

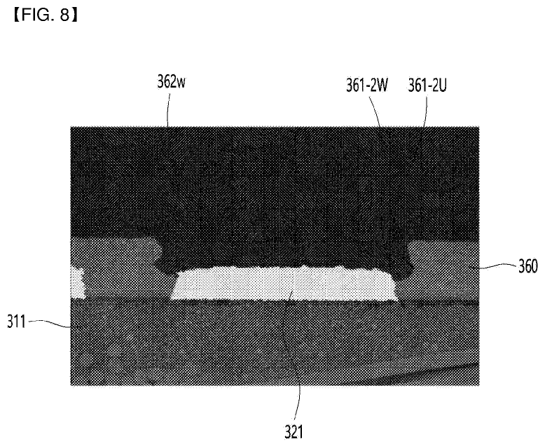

FIG. 7 is a diagram showing a circuit board according to the fourth embodiment, and FIG. 8 is an optical microscope photo of the actual product corresponding to FIG. 7.

Referring to FIGS. 7 and 8, the circuit board according to the fourth embodiment includes a first insulating layer 311. Additionally, the first pad 321 of the first circuit pattern layer is disposed on the first insulating layer 311. Additionally, a first protective layer 360 including a first opening vertically overlapping the first pad 321 is disposed on the first insulating layer 311. At this time, the first protective layer 360 includes a first portion 361 and a second portion 362 disposed on the first portion 361. The first portion 361 of the first protective layer 360 includes a first-first portion 361-1 disposed on the upper surface of the first insulating layer 311 and including a first side wall 361-1W in direct contact with at least a portion of the side surface of the first pad 321. Additionally, the first portion 361 of the first protective layer includes a first-second portion 361-2 disposed on the upper surface of the first-first portion 361-1. And, the first-second portion (361-2) includes a first-first opening OR1-1 including a second side wall 361-2W having a certain inclination angle with respect to the upper surface of the first insulating layer 311. Additionally, the second portion 362 of the first protective layer includes a first-second opening OR1-2 disposed on the first-second portion (361-2) and connected to the first-first opening OR1-1. Additionally, the second portion 362 of the first protective layer may include a third side wall 362W corresponding to the first-second opening OR1-2.

At this time, the third side wall 362W of the first-second opening OR1-2 may include a rounded curved surface. For example, the first-second opening OR1-2 may include a region whose width varies. For example, the process of forming the first opening OR1 in the first protective layer includes a process of determining the width of the uppermost part of the first-second opening OR1-2 to correspond to the target width of the first opening OR1, and processes of exposure and development according to the determination. At this time, depending on a viscosity of a material forming the first protective layer, the third side wall 362W may have an inclination substantially perpendicular to the upper or lower surface of the first protective layer, or may have a different curved surface.

For example, the first-second opening OR1-2 may include a portion whose width changes. For example, the third side wall 362W may include a third-first side wall 362W1 and a third-second side wall 362W2.

In addition, a width of the first-second opening OR1-2 in the third-first side wall 362W1 may be smaller than a width of the first-second opening OR1-2 in the third-second side wall 362W2. For example, the third-first side wall 362W1 may protrude in an inner direction of the first opening toward the first pad relative to the 3-2 side wall 362W2.

Through this, when the pad exposed through the opening region SRO and solder ball are connected, the solder ball can improve the adhesion with the solder resist of the board, solving the problem of separation between the board and the solder ball.

Additionally, the first protective layer 360 may include a depression 361-2U.

The depression 361-2U may refer to an undercut portion that is depressed in the side wall of the first protective layer 360 toward the inside of the first protective layer 260 (or in a direction away from the first pad).

The depression 361-2U may be formed in a boundary region between the first portion 361 and the second portion 362 of the first protective layer 360. For example, a distinction between the first portion 361 and the second portion 362 of the first protective layer 360 may be made based on the position of the depression 361-2U.

At this time, the embodiment may prevent the depression from being formed on the side wall of the first opening of the first protective layer. Furthermore, in the embodiment, even if the depression 361-2U is formed on the side wall of the first opening OR1 of the first protective layer 360, the horizontal or vertical distance of the depression 361-2U can be reduced, as a result this prevents reliability problems caused by the depression 361-2U.

That is, in the embodiment, the entire thickness of the first protective layer 360 is not opened, but only the remaining portion excluding the first portion of the first protective layer 360 is developed and opened, as a result, the horizontal distance W1 and vertical distance H3 of the depression 361-2U can be reduced compared to the comparative example.

At this time, the horizontal distance W1 of the depression 361-2U may refer to a horizontal distance between an innermost end of the depression 361-2U and a lowermost end of the side wall of the second portion 362 of the adjacent first protective layer 360. Differently, the horizontal distance W1 of the depression 361-2U may refer to a horizontal distance between an innermost end of the depression 361-2U and an uppermost end of the first portion 361 of the adjacent first protective layer 360. In addition, the vertical distance H3 of the depression 361-2U may refer to the vertical distance between an uppermost end of the first portion 362 of the first protective layer 360 connected to the depression 361-2U and a lowermost end of the first protective layer 360 connected to the depression 361-2U.

In addition, in an embodiment, the horizontal distance W1 may be 13 um or less. For example, the horizontal distance W1 in the embodiment may be 10 μm or less. For example, the horizontal distance W1 of the depression 361-2U in the embodiment may be 6 um or less. For example, the horizontal distance W1 of the depression 361-2U in the embodiment may be 2 um or less. Through this, the embodiment can reduce the horizontal distance W1 of the depression 361-2U compared to the comparative example, thereby reducing the first pad and the gap between the first pad and the adjacent trace. For example, a distance between the first pad and the trace is determined by considering the horizontal distance of the depression. For example, the distance between the first pad and the trace may be determined to be approximately 120% of the horizontal distance of the depression. At this time, the horizontal distance of the depression in the comparative example was at least 40 um. Accordingly, the distance between the first pad and the trace in the comparative example had a minimum of 48 um. Differently, the embodiment can dramatically reduce the distance between the first pad and the trace compared to the comparative example, thereby enabling miniaturization of the circuit board or improving circuit integration.

Additionally, the vertical distance H3 of the depression 361-2U in the embodiment may be 13 um or less. For example, the vertical distance H3 of the depression 361-2U in the embodiment may be 10 um or less. For example, the vertical distance H3 of the depression 361-2U in the embodiment may be 6 um or less. For example, the vertical distance H3 of the depression 361-2U in the embodiment may be 2 um or less.

In addition, the depression 361-2U may have the same horizontal and vertical distances as above, and may have an angle smaller than the inclination angle θ1.

### —Package Substrate—

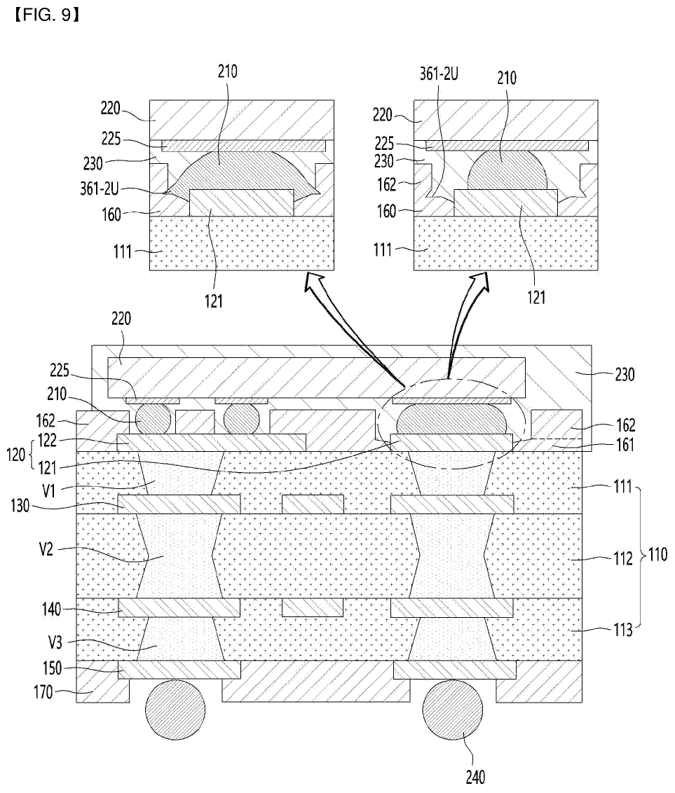

FIG. 9 is a diagram showing a package substrate according to an embodiment.

The package substrate may have a structure in which a semiconductor device is disposed on the first or second circuit board shown in any one of FIGS. 2A to 2G.

For example, referring to FIG. 9, the package substrate of the embodiment may have a structure in which at least one chip is mounted on the circuit board of FIG. 3A. At this time, the structure shown in any one of FIGS. 3A to 7 may be applied to the first opening in the first region of the circuit board of the package substrate in FIG. 9. Additionally, in an embodiment, the first region of the circuit board may include a plurality of first openings of different structures and spaced apart in the width or length direction, one of the plurality of first openings may have the structure shown in any one of FIGS. 3A to 7, and another one of the plurality of first openings may have the structure shown in another one of FIGS. 3A to 7.

For example, the package substrate may include a first connection part 210 disposed on the first pad 121 and the second pad 122 of the first circuit pattern layer 120 disposed on the first outermost side of the circuit board.

The first connection part 210 may have a spherical shape. For example, the cross section of the first connection part 210 may include a circular shape or a semicircular shape. For example, the cross section of the first connection part 210 may include a partially or entirely rounded shape. For example, a cross-sectional shape of the first connection part 210 may be flat on one side and curved on the other side. The first connection part 210 may be a solder ball, but is not limited thereto.

Meanwhile, the first connection part 210 may fill at least a portion of the depression 361-2U formed in the first protective layer 160 of the circuit board. For example, at least a portion of the first connection part 210 may penetrate into the depression 361-2U during a reflow process, through this, the depression 361-2U can be filled with the first connection part 210.

The package substrate of the embodiment may include a chip 220 disposed on the first connection part 210. The chip 220 may be a processor chip. For example, the chip 220 may be an application processor (AP) chip of any one of a central processor (e.g., CPU), a graphics processor (e.g., GPU), a digital signal processor, a cryptographic processor, a microprocessor, and a microcontroller.

At this time, a terminal 225 may be included on the lower surface of the chip 220, and the terminal 225 may be electrically connected to the pads 121 and 122 of the first circuit pattern layer 120 of the circuit board through the first connection part 210.

Meanwhile, the package substrate of the embodiment may allow a plurality of chips to be arranged at a certain distance from each other on one circuit board. For example, the chip 220 may include a first chip and a second chip that are spaced apart from each other.

Also, the first chip and the second chip may be different types of application processor (AP) chips.

Meanwhile, the first chip and the second chip may be spaced apart from each other at a certain distance on the circuit board. For example, the distance between the first chip and the second chip may be 150 μm or less. For example, the distance between the first chip and the second chip may be 120 μm or less. For example, the distance between the first chip and the second chip may be 100 μm or less.

Preferably, for example, the distance between the first chip and the second chip may range from 60 um to 150 um. For example, the distance between the first chip and the second chip may range from 70 μm to 120 μm. For example, the distance between the first chip and the second chip may range from 80 um to 110 um. For example, if the distance between the first chip and the second chip is less than 60 um, interference between the first chip and the second chip may cause problems with the operational reliability of the first chip or the second chip. For example, if the distance between the first chip and the second chip is greater than 150 um, signal transmission loss may increase as the distance between the first chip and the second chip increases.

The package substrate may include a molding layer 230. The molding layer 230 may be disposed to cover the chip 220. For example, the molding layer 230 may be EMC (Epoxy Mold Compound) formed to protect the mounted chip 220, but is not limited thereto.

At this time, if the depression 361-2U is not filled through the first connection part 210, the depression 361-2U may be filled by the molding layer 230.

For example, as shown in the first enlarged view of FIG. 9, the depression 361-2U may be filled by the first connection part 210. That is, in the process of mounting the chip 220 on the first connection part 210, a reflow process of the first connection part 210 may be performed. Also, in the reflow process, the first connection part 210 may spread, and accordingly, the depression 361-2U may be filled by the first connection part 210.

For example, as shown in the second enlarged view of FIG. 9, during the reflow process of the first connection part 210, the first connection part 210 may not spread to the depression 361-2U. At this time, the depression 361-2U may be filled by the molding layer 230.

For example, although not shown in FIG. 9, during the reflow process of the first connection part 210, the first connection part 210 may be formed to spread up to the third side wall 362w of FIG. 7.

At this time, the molding layer 230 may have a low dielectric constant to increase heat dissipation characteristics. For example, the dielectric constant (Dk) of the molding layer 230 may be 0.2 to 10. For example, the dielectric constant (Dk) of the molding layer 230 may be 0.5 to 8. For example, the dielectric constant (Dk) of the molding layer 230 may be 0.8 to 5. Accordingly, the embodiment allows the molding layer 230 to have a low dielectric constant, thereby improving heat dissipation characteristics for heat generated from the chip 220.

Meanwhile, the package substrate may include a second connection part 240 disposed on a lowermost side of the circuit board. The second connection part 240 may be for bonding between the package substrate and an external substrate (e.g., a main board of an external device).

Hereinafter, a method of manufacturing a circuit board according to an embodiment will be described.

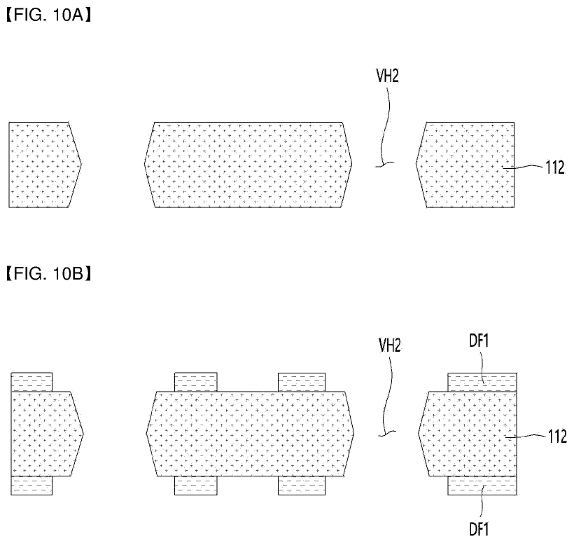

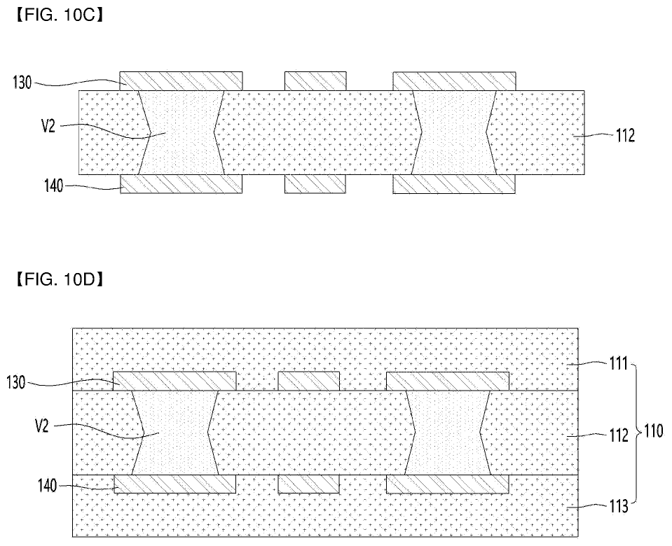

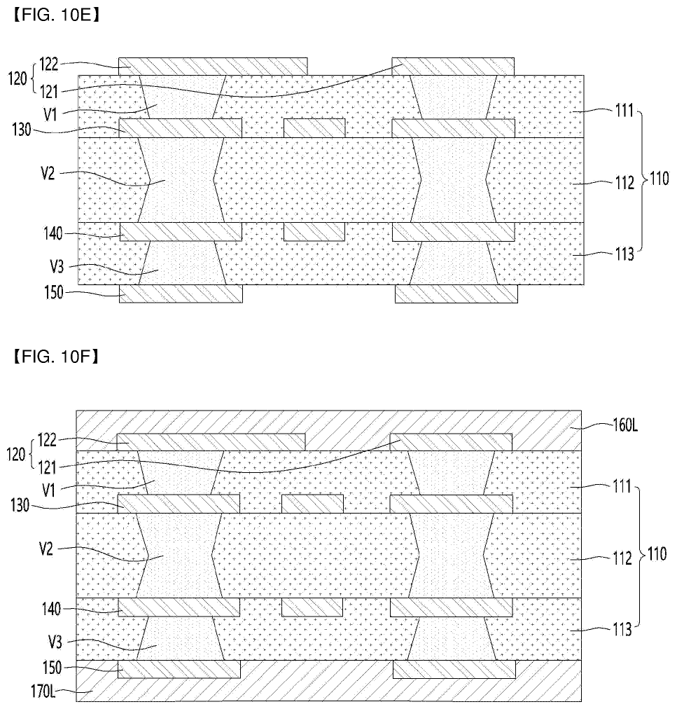

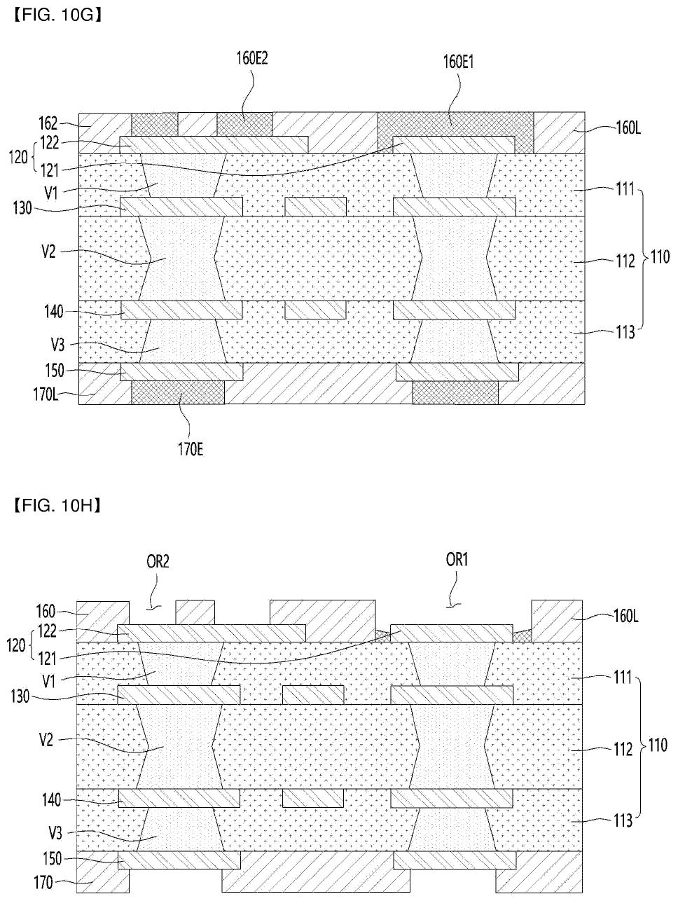

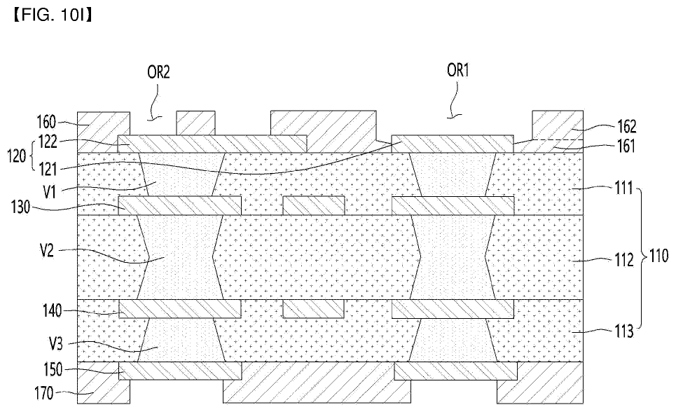

FIGS. 10A to 10I are diagrams showing the method of manufacturing the circuit board according to the first embodiment in order of processes.

Referring to FIG. 10A, in the embodiment, the second insulating layer 112 is prepared. The second insulating layer 112 may be a core layer. And, when the second insulating layer 112 is a core layer, the second insulating layer 112 may be CCL (Copper Clad Laminate). In addition, the embodiment may proceed with a process of forming a second through hole VH2 passing through the second insulating layer 112. At this time, the second insulating layer 112 is a core layer having a certain thickness or more, and accordingly, the process of forming the second through hole VH2 may include a first process of forming a first part of the second through hole VH2 on an upper side of the second insulating layer 112, and a second process of forming a second part connected to the first part of the second through hole VH2 on a lower side of the second insulating layer 112. Accordingly, the second through hole VH2 may have an hourglass shape according to the combination of the first part and the second part. Meanwhile, although not shown in FIG. 8A, copper foil layers (not shown) may be laminated on the upper and lower surfaces of the second insulating layer 112, respectively.

Next, the embodiment may proceed with a process of forming a second through electrode 170 filling the second through hole VH2 of the second insulating layer 112 and a process of forming the second circuit pattern layer 130 disposed on the upper surface of the second insulating layer 112 and the third circuit pattern layer 140 disposed on the lower surface of the second insulating layer 112.

To this end, as shown in FIG. 10B, the embodiment may proceed with a process of forming a dry film DF1 having an opening exposing a region where the second circuit pattern layer 130 and the third circuit pattern layer 140 will be formed on the upper and lower surfaces of the second insulating layer 112.

And, as shown in FIG. 10C, the embodiment may proceed with a process of forming the second through electrode V2, the second circuit pattern layer 130, and the third circuit pattern layer 140 by performing plating to fill the second through hole VH2 and the opening of the dry film DF1. At this time, the embodiment allows electroless plating to be performed on the second insulating layer 112 or the copper foil layer (not shown) to form a chemical copper plating layer (not shown), and accordingly, the plating may be performed using the chemical copper plating layer as a seed layer.

Next, as shown in FIG. 10D, the embodiment may proceed with a process of laminating the first insulating layer 111 on the first or upper surface of the second insulating layer 112 and a process of laminating the third insulating layer 113 on the second or lower surface of the second insulating layer 112 may be performed.

At this time, the first insulating layer 111 and the third insulating layer 113 may be prepreg or, alternatively, may be RCC.

In addition, although not shown in the drawing, a copper foil layer (not shown) may be formed on the first surface of the first insulating layer 111 and the second surface of the third insulating layer 113, respectively.

Next, as shown in FIG. 10E, the embodiment may proceed with a process of forming a first through electrode V1 and a third through electrode V3 to fill the through hole VH1 and VH3, and a process of forming a first circuit pattern layer 120 on the upper surface of the first insulating layer 111 and a fourth circuit pattern layer 150 on the lower surface of the third insulating layer 113, by plating.

Next, as shown in FIG. 10F, the embodiment is a process of forming a first solder resist layer 160L on the upper surface of the first insulating layer 111 and a process of forming a second solder resist layer 170L on the lower surface of the third insulating layer 113. At this time, the first solder resist layer 160L and the second solder resist layer 170L may be formed entirely on the upper part of the first insulating layer 111 and the lower part of the third insulating layer 113.

Next, as shown in FIG. 10G, the embodiment may proceed with a process of exposing the first solder resist layer 160L and the second solder resist layer 170L, respectively.

For example, the embodiment may proceed with a process of exposing the remaining regions of the first solder resist layer 160L except the region 160E1 where the first opening OR1 will be formed and the region 160E2 where the second opening OR2 will be formed. Additionally, the embodiment may proceed with a process of exposing the remaining regions of the second solder resist layer 170L except the region 170E where the opening will be formed may be performed.

Thereafter, the embodiment may proceed with a process of curing the exposed region according to the exposure process. However, the curing process may not be carried out separately but may be carried out together with the exposure process.

Next, as shown in FIG. 10h, the embodiment may proceed with a process of forming an opening by developing the uncured regions (160E1, 160E2, 170E) excluding the cured region.

At this time, in order to form the opening, the embodiment may proceed with a process of thinning the uncured regions (160E1, 160E2, 170E) to reduce the thickness of the solder resist layer in the corresponding region. At this time, the thinning can be performed on the unexposed region using an organic alkaline compound containing tetramethylammonium hydroxide (TMAH) or trimethyl-2-hydroxyethylammonium hydroxide (choline).

Accordingly, the embodiment can adjust the conditions in the thinning process and allow only a portion of the region 160E1 of the first solder resist layer 160L to be removed, rather than the entire region 160E1. Through this, the embodiment allows the first protective layer 160 including the first opening OR1 and the second opening OR2 and the second protective layer 170 including the opening to be formed.

Thereafter, in the embodiment, as shown in FIG. 10I, the entire region 160E1 is not removed, but only a part of it is removed. Accordingly, the embodiment may proceed with a process of hardening the unrecovered region. Through this, the embodiment can form a first region including the first opening OR1 and a second region including the second opening OR2 while including the first portion and the second portion of the first protective layer described above,

As described above, the first region R1 of the first protective layer 160 in the first embodiment includes a first opening OR1 that vertically overlaps the first pad 121 and has a larger width than the first pad 121.

In addition, the first protective layer 160 includes a first portion 161 disposed on the upper surface of the first insulating layer 111 and a second portion 162 disposed on the first portion 161.

In addition, the first portion 161 of the first protective layer 160 includes a first-first portion 161-1 in contact with the side surface of the first pad 121 and a first-second portion 161-2 disposed on the first-first portion 161-1 and spaced apart from the side of the first pad 121. And, the embodiment allows a portion of the side surface of the first pad 121 to be covered through the first-first portion 161-1. Through this, the embodiment can allow to solve the problem of exposing a portion of the upper surface of the first insulating layer as the first opening OR1 in the first region R1 has a width greater than the width of the first pad 121. Accordingly, damage to the upper surface of the first insulating layer can be prevented. Additionally, when forming the first opening OR1 in the first protective layer 160, the embodiment does not completely open the first protective layer 160, but allows only the region excluding the first-first portion 161-1 to be partially opened, and accordingly, the process time can be dramatically reduced and the process yield can be improved accordingly. Additionally, the embodiment can solve the problem that the undercut depth increases in proportion to the depth of the first opening OR1. For example, the embodiment allows the first opening OR1 to be formed by partially developing only the region excluding the first-first portion 161-1, and accordingly, the depth of the undercut can be reduced, and further, the undercut can be prevented from being formed on the sidewall of the first protective layer 160 having the first opening OR1. In addition, the embodiment may control the thickness of the first-first portion 161-1 to reduce the height of the step between the first-first portion 161-1 and the first pad, and accordingly, it is possible to solve the void problem that occurs when a connection part such as a solder ball is not completely filled within the first opening. Additionally, the second side wall 161-2W of the first-second portion 161-2 has an inclination angle θ1 that inclines toward the second portion 162 as the distance from the first pad 121 increases. Accordingly, the embodiment can improve the flowability of the connection part by using the inclination angle θ1 in a process of applying the connection part within the first opening OR1, and accordingly, the connection part can be placed on the first pad 121 vertically overlapping the first opening OR1. Through this, the embodiment can improve adhesion between the first pad and the connection part, thereby improving electrical reliability and physical reliability.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

1. A circuit board comprising:
an first insulating layer;
a first pad disposed on the first insulating layer; and
a first protective layer disposed on the first insulating layer and having a first through hole vertically overlapping the first pad,
wherein an inner wall of the first through hole includes a contact surface in contact with a side surface of the first pad, and a non-contact surface located on the contact surface, and
wherein the non-contact surface includes:
a first portion connected to an upper end of the contact surface and having a first slope in a direction away from the first pad; and
a second portion located on the first portion and having a second slope different from the first slope,
wherein an upper end of the second portion of the non-contact surface is located higher than an upper surface of the first pad.

2. The circuit board of claim 1, wherein at least a portion of the first portion of the non-contact surface overlaps the first pad in a horizontal direction.

3. The circuit board of claim 2, wherein a width of the first portion in a horizontal direction is greater than a width of each of the second portion and the contact surface in the horizontal direction.

4. The circuit board of claim 3, wherein the first protective layer includes a region overlapping the first portion of the non-contact surface in a vertical direction and gradually decreasing in thickness toward the side surface of the first pad.

5. The circuit board of claim 3, wherein the slope of the second portion is closer to vertical than the slope of the first portion.

6. The circuit board of claim 3, wherein the first pad includes an overlapping portion overlapping the contact surface in a horizontal direction,
wherein a thickness of the overlapping portion satisfies a range of 50% to 98% of a thickness of the first pad.

7. The circuit board of claim 3, wherein a width in the horizontal direction between the first portion of the non-contact surface and a side surface of the first pad increases gradually along a vertical direction from the contact surface towards the second portion,
a width of an inner wall of the first portion gradually increases as it approaches the second portion.

8. The circuit board of claim 4, wherein an internal angle between the first portion and the lower surface of the first protective layer satisfies the range of 10 degrees to 70 degrees.

9. The circuit board of claim 4, wherein a vertical length between the lower surface of the first protective layer and an uppermost end of the first portion satisfies the range of 70% to 130% of a vertical length between a lower surface and an upper surface of the first pad.

10. The circuit board of claim 4, wherein at least one of an upper and side surfaces of the first pad includes a curved surface.

11. The circuit board of claim 1, wherein a lower end of the first portion is located lower than the upper surface of the first pad, and an upper end of the first portion is located higher than the upper surface of the first pad.

12. The circuit board of claim 4, wherein a width in the horizontal direction between the second portion and a side surface of the first pad is equal along the vertical direction.

13. The circuit board of claim 1, further comprising:
a second pad on the first insulating layer spaced apart from the first pad in a horizontal direction,
wherein the first protective layer includes a second through hole overlapping the second pad in a vertical direction,
wherein a slope of an inner wall of the second through hole is different from a slope of an inner wall of the first through hole.

14. The circuit board of claim 13, wherein a width of the inner wall of the second through hole is smaller than a width of the second pad.

15. The circuit board of claim 13, wherein the second through hole includes a plurality of sub-through holes overlapping one second pad in the vertical direction and spaced apart in the horizontal direction.

16. The circuit board of claim 1, wherein a depression is provided between the first portion and the second portion and is recessed in an inner direction of the first protective layer away from the first pad.

17. The circuit board of claim 16, wherein at least a portion of the depression is located higher than the upper surface of the first pad.

18. The circuit board of claim 16, wherein at least a portion of the depression is located lower than the upper surface of the first pad.

19. A semiconductor package comprising:
an first insulating layer;
a first pad disposed on the first insulating layer;
a first protective layer disposed on the first insulating layer and having a first through hole vertically overlapping the first pad; and
a semiconductor device disposed on the first pad,
wherein an inner wall of the first through hole includes a contact surface in contact with a side surface of the first pad, and a non-contact surface located on the contact surface, and
wherein the non-contact surface includes:
a first portion connected to an upper end of the contact surface and having a first slope in a direction away from the first pad; and
a second portion located on the first portion and having a second slope different from the first slope,
wherein an upper end of the second portion of the non-contact surface is located higher than an upper surface of the first pad.

20. The semiconductor package of claim 19, further comprising:
a molding layer for molding the semiconductor device,
wherein the first protective layer includes a depression provided between the first portion and the second portion and recessed in an inner direction of the first protective layer away from the first pad, and
wherein the molding layer is provided to fill the depression.
